(19) United States
(12) Patent Application Publication
(10) Pub. No.: US 2021/0126164 A1
(43) Pub. Date: Apr. 29, 2021

(54) RED MICRO-LED WITH DOPANTS IN ACTIVE REGION

(71) Applicant: Facebook Technologies, LLC, Menlo Park, CA (US)

(72) Inventors: Markus BROELL, Cork (IE); David HWANG, Waterloo (CA); Steven David LESTER, Redmond, WA (US); Anurag TYAGI, Kirkland, WA (US); Michael GRUNDMANN, Kirkland, WA (US); Guillaume LHEUREUX, Cork (IE); Alexander TONKIKH, Cork (IE)

(21) Appl. No.: 17/081,935

(22) Filed: Oct. 27, 2020

Related U.S. Application Data
(60) Provisional application No. 62/927,452, filed on Oct. 29, 2019.
(60) Provisional application No. 63/079,703, filed on Sep. 17, 2020.

(51) Int. Cl. H01L 33/30; H01L 33/00; H01L 33/06; H01L 25/075

(52) U.S. Cl. CPC H01L 33/305; H01L 25/0753; H01L 33/06; H01L 33/0008

(57) ABSTRACT

A light source includes a p-type semiconductor layer, an n-type semiconductor layer, and an active region between the p-type semiconductor layer and the n-type semiconductor layer and configured to emit light. The active region includes a plurality of barrier layers and one or more quantum well layers. The plurality of barrier layers of the active region includes at least one n-doped barrier layer that includes an n-type dopant. The active region is characterized by a lateral linear dimension equal to or less than about 10 μm. The n-type dopant includes, for example, silicon, selenium, or tellurium.

### CROSS-REFERENCE TO RELATED APPLICATIONS

This patent application claims priority to U.S. Provisional Patent Application Ser. No. 62/927,452, filed Oct. 29, 2019, entitled “MICRO-LEDS WITH DOPANTS INTRODUCED IN ACTIVE REGIONS,” and U.S. Provisional Patent Application Ser. No. 63/079,703, filed Sep. 17, 2020, entitled “RED EPI FOR MICROLEDS WITH DOPING INSIDE THE BARRIERS,” both of which are herein incorporated by reference in their entireties for all purposes.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-V semiconductors, such as alloys of AlN, GaN, InN, GaAs, GaInP, AlGaInP, other quaternary phosphide compositions, and the like, have begun to be developed for various display applications due to their small size, high packing density, higher resolution, and high brightness. For example, micro-LEDs that emit light of different colors (e.g., red, green, and blue) can be used to form the sub-pixels of a display system, such as a television or a near-eye display system.

### SUMMARY

This disclosure relates generally to micro light emitting diodes (micro-LEDs). More specifically, this disclosure relates to improving the quantum efficiencies of small micro-LEDs, such as an AlGaInP-based red micro-LED with an active region characterized by a lateral linear dimension (e.g., a diameter or a side) less than about 10 μm. According to certain embodiments, a light source may include a p-type semiconductor layer, an n-type semiconductor layer, and an active region between the p-type semiconductor layer and the n-type semiconductor layer and configured to emit light. The active region may include a plurality of barrier layers and one or more quantum well layers. The plurality of barrier layers of the active region may include at least one n-doped barrier layer that includes an n-type dopant. The active region may be characterized by a lateral linear dimension equal to or less than about 10 μm. In some embodiments, the lateral linear dimension of the active region may be equal to or less than about 5 μm.

In some embodiments, the active region may include an AlInGaP, AlGaAs, or InGaAlAsP based material. The n-type dopant may include, for example, silicon, selenium, or tellurium. In some embodiments, the concentration of the n-type dopant in the at least one n-doped barrier layer may be between about 1×10¹⁷/cm³ and about 5×10¹⁸/cm³. The active region may be configured to emit light characterized by a wavelength equal to or greater than about 590 nm. In some embodiments, the current density of the light source to achieve a peak efficiency may be greater than about 10 A/cm².

In some embodiments, the at least one n-doped barrier layer may include an n-doped barrier layer next to the p-type semiconductor layer. In some embodiments, the at least one n-dope barrier layer may include an undoped region between a doped region of the at least one n-doped barrier layer and a neighboring quantum well layer in the plurality of quantum well layers. In some embodiments, the at least one n-doped barrier layer may include a single n-doped barrier layer that physically contacts the p-type semiconductor layer. In some embodiments, the at least one n-doped barrier layer may include two or more n-doped barrier layers. In some embodiments, each of the plurality of barrier layers may include the n-type dopant. The n-type dopant may be introduced into the at least one n-doped barrier layer during the epitaxial growth of the active region. The p-type semiconductor layer may be epitaxially grown on the active region to form a p-side-up device. In some embodiments, the one or more quantum well layers of the active region may include a single quantum well layer.

According to some embodiments, a display device may include a two-dimensional array of micro-LEDs. Each micro-LED of the two-dimensional array of micro-LEDs may include a p-type semiconductor layer, an n-type semiconductor layer, and an active region between the p-type semiconductor layer and the n-type semiconductor layer and configured to emit visible light. The active region may include a plurality of barrier layers and one or more quantum well layers. The plurality of barrier layers of the active region may include at least one n-doped barrier layer that includes an n-type dopant. The active region may be characterized by a lateral linear dimension equal to or less than about 10 μm.

In some embodiments of the display device, the active region of each micro-LED may include an AlInGaP, AlGaAs, or InGaAlAsP based material. The n-type dopant may include, for example, silicon, selenium, or tellurium. The concentration of the n-type dopant in the at least one n-doped barrier layer may be between about 1×10¹⁷/cm³ and about 5×10¹⁸/cm³. In some embodiments, the active region may include only one quantum well layer.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIG. 8 illustrates the relationship between the optical emission power and the current density of a light emitting diode.

FIG. 9 illustrates surface recombination velocities of various III-V semiconductors.

FIG. 10A illustrates external quantum efficiencies of examples of AlGaInP red micro-LEDs of different sizes as a function of the injected current density.

FIG. 10B illustrates current densities of examples of AlGaInP red micro-LEDs of different sizes at different bias voltages.

FIG. 11A illustrates the relationship between the external quantum efficiency and the current density for two micro-LEDs having the same size, where the first micro-LED is not intentionally doped in the active region while the second micro-LED is intentionally doped in the active region.

FIG. 11B illustrates external quantum efficiencies of examples of micro-LEDs of different sizes and with or without doping in the active regions as a function of the injected current density.

FIG. 12A illustrates an example of a red micro-LED with no doping in the active region.

FIG. 12B illustrates an example of a red micro-LED with doping in the barrier layers of a multi-quantum well (MQW) structure according to certain embodiments.

FIG. 12C illustrates an example of a red micro-LED with doping in one or more but not all barrier layers of an MQW structure according to certain embodiments.

FIG. 12D illustrates an example of a red micro-LED with doping in the middle portion of each barrier layer of an MQW structure according to certain embodiments.

FIG. 13A illustrates an example of a red micro-LED with doping in the barrier layers of a quantum well structure according to certain embodiments.

FIG. 13B illustrates an example of a red micro-LED with doping in a barrier layer of a quantum well structure according to certain embodiments.

FIG. 13C illustrates an example of a red micro-LED with doping in the middle portion of a barrier layer of a quantum well structure according to certain embodiments.

FIG. 14 illustrates external quantum efficiencies of examples of micro-LEDs having different sizes and different doping recipes in the active regions at a same driving current.

FIG. 15 illustrates external quantum efficiencies of examples of micro-LEDs having different sizes and different doping recipes in the active regions at a same current density.

FIG. 16A illustrates external quantum efficiencies of examples of n-side-up micro-LEDs having different sizes and different doping recipes in the active regions at a same current density.

FIG. 16B illustrates external quantum efficiencies of examples of p-side-up micro-LEDs having different sizes and different doping recipes in the active regions at a same current density.

FIG. 17 illustrates an example of a micro-LED structure used for simulations according to certain embodiments.

FIG. 18A illustrates simulated electron densities in the quantum wells of examples of small micro-LEDs without or with doping in the barrier layers according to certain embodiments.

FIG. 18B illustrates simulated hole densities in the quantum wells of examples of small micro-LEDs without or with doping in the barrier layers according to certain embodiments.

FIG. 19 illustrates simulated radiative recombination rates in the quantum wells of examples of small micro-LEDs without or with doping in the barrier layers according to certain embodiments.

FIG. 20A illustrates the energy bands at the center regions of examples of small micro-LEDs without or with doping in the barrier layers according to certain embodiments.

FIG. 20B illustrates carrier densities in different layers of examples of small micro-LEDs without or with doping in the barrier layers according to certain embodiments.

FIG. 20C illustrates radiative recombination rates in different layers of examples of small micro-LEDs without or with doping in the barrier layers according to certain embodiments.

FIG. 21A illustrates simulated lateral electron current densities in quantum wells of examples of small micro-LEDs without or with doping in the barrier layers according to certain embodiments.

FIG. 21B illustrates simulated lateral hole current densities in quantum wells of examples of small micro-LEDs without or with doping in the barrier layers according to certain embodiments.

FIG. 22A illustrates simulated internal quantum efficiencies of examples of large micro-LEDs having different doping recipes in the active regions as a function of the injected current density.

FIG. 22B illustrates simulated internal quantum efficiencies of examples of small micro-LEDs having different doping recipes in the active regions as a function of the injected current density.

FIG. 23A illustrates measured external quantum efficiencies of examples of small micro-LEDs having the same size but different doping recipes in the active regions as a function of the injected current density.

FIG. 23B illustrates examples of measured external quantum efficiencies of micro-LEDs having different sizes and different doping recipes in the active regions at a same injected current density.

FIG. 24 illustrates additional measurement results showing efficiency improvement for examples of micro-LEDs with dopants in the active regions according to certain embodiments.

FIG. 25 illustrates additional measured external quantum efficiencies of examples of micro-LEDs having different lateral sizes and without or with dopants in the active regions according to certain embodiments.

FIG. 26A illustrates an example of a method of die-to-wafer bonding for arrays of LEDs according to certain embodiments.

FIG. 26B illustrates an example of a method of wafer-to-wafer bonding for arrays of LEDs according to certain embodiments.

FIGS. 27A-27D illustrates an example of a method of hybrid bonding for arrays of LEDs according to certain embodiments.

FIG. 28 illustrates an example of an LED array with secondary optical components fabricated thereon according to certain embodiments.

FIG. 29 is a simplified block diagram of an electronic system of an example of a near-eye display according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to micro-light emitting diodes (micro-LEDs). More specifically, and without limitation, disclosed herein are techniques for improving the quantum efficiency of small micro-LEDs, such as AlGaAs or AlGaInP-based red micro-LEDs with active regions characterized by a linear dimension less than about 20 μm, at high injected current densities. Various inventive embodiments are described herein, including devices, systems, methods, materials, processes, and the like.

In semiconductor light emitting diodes (LEDs), photons are usually generated at a certain internal quantum efficiency (IQE) through the recombination of electrons and holes within an active region (e.g., including one or more quantum well layers. The internal quantum efficiency may be the proportion of the radiative electron-hole recombination in the active region that emits photons. The generated light may then be extracted from the LEDs in a particular direction or within a particular solid angle. The ratio between the number of emitted photons extracted from an LED and the number of electrons injected into the LED is generally referred to as the external quantum efficiency (EQE), which describes how efficiently the LED converts injected electrons to photons that are extracted from the LED. For LEDs, and in particular, micro-LEDs with reduced physical dimensions, the internal and external quantum efficiencies may be very low, and improving the quantum efficiency of the LEDs can be challenging.

The quantum efficiency of LEDs may depend on the relative rates of competitive radiative (light producing) recombination and non-radiative (lossy) recombination that occur in the active region of the LEDs. Non-radiative recombination processes in the active region include Shockley-Read-Hall (SRH) recombination at defect sites and electron-electron-hole (eeh) and/or electron-hole-hole (ehh) Auger recombination, which is a non-radiative process involving three carriers. In micro-LEDs, because the size of a micro-LED may be comparable to the minority carrier diffusion length, a larger proportion of the total active region may be within a distance less than the minority carrier diffusion length from the mesa sidewall surfaces where the defect density and the non-radiative recombination rate may be high. Therefore, more injected carriers may diffuse to the regions near the mesa sidewall surfaces and may be subjected to the higher SRH recombination rate. This may cause the peak efficiency of the LED to decrease or cause the peak efficiency operating current to increase. Increasing the current injection may cause the efficiencies of the micro-LEDs to drop due to the higher eeh or ehh Auger recombination rate at a higher current density. As the physical sizes of LEDs further reduce, efficiency losses due to surface recombination near the etched sidewall facets that include surface imperfections become much more significant.

Compared with, for example, GaN-based material systems, AlGaAs, InGaAlAsP, and AlGaInP materials may have high surface recombination velocities and minority carrier diffusion lengths. Thus, InGaAlAsP, AlGaAs, and AlGaInP-based red or near-infrared light-emitting devices (e.g. LEDs/VCSELs) may suffer from high surface losses, especially for devices with active regions having lateral sizes less than about 50 μm, less than about 20 μm, or less than about 10 μm. For example, carriers in AlGaInP materials can have high diffusivity (mobility), and AlGaInP materials may have an order of magnitude higher surface recombination velocity than III-nitride materials. Thus, the internal and external quantum efficiencies of red LEDs may drop even more significantly as the device size reduces due to enhanced surface losses.

For large red LEDs, doping in the active regions (e.g., in the barrier layers) is generally not desired because dopants in the active regions can form defects and thus can reduce the efficiencies of the devices at high current densities during normal operations, even though the quantum efficiencies (e.g., determined by measuring the photoluminescence) at low current densities (e.g., less than about 1 A/cm², such as few tens mA/cm²) may improve by the doping in the active region. However, it is determined in the present disclosure that, for devices with lateral sizes less than certain threshold values (which may depend on the doping density and/or the operating current density), such as less than about 20 μm, less than about 10 μm, or less than about 8 μm, doping in the active regions can significantly improve the efficiencies at the device operation conditions (e.g., with current densities greater than about 10 A/cm²) due to the suppression of surface losses.

According to certain embodiments, the active region of small red micro-LEDs having pixel sizes less than, for example, about 20 or about 10 μm, may be intentionally n-doped during the epitaxial growth to improve the EQEs of the micro-LEDs at high current densities, such as 10 A/cm² or higher. Examples of the dopants include selenium, silicon, or tellurium, which may be less likely to diffuse into the quantum wells during the epitaxial growth. The dopant concentration can range from, for example, about 1×10¹⁷/cm³ to about 5×10¹⁸/cm³ or about 1×10¹⁹/cm³. In some embodiments, the dopants may only be added in one or more but not all barrier layers to reduce the potential impact of non-radiative recombination mechanisms associated with dopant-related defects or defect-complexes. In one example, only the top barrier layer on the p-side is doped. In some embodiments, each of the doped one or more barrier layers may include an additional setback layer between the doped region and the adjacent quantum well to further improve the efficiency due to the reduction of non-radiative recombination. In some embodiments, the active region may only include one quantum well. In some embodiments, the micro-LEDs may be p-side-up micro-LEDs.

The micro-LEDs described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

As used herein, the term “light emitting diode (LED)” refers to a light source that includes at least an n-type semiconductor layer, a p-type semiconductor layer, and a light emitting region (i.e., active region) between the n-type semiconductor layer and the p-type semiconductor layer. The light emitting region may include one or more semiconductor layers that form one or more heterostructures, such as quantum wells. In some embodiments, the light emitting region may include multiple semiconductor layers that form one or more multiple-quantum-wells (MQWs), each including multiple (e.g., about 2 to 6) quantum wells.

As used herein, the term “micro-LED” or “μLED” refers to an LED that has a chip where a lateral linear dimension (e.g., the diameter or a side) of the active region of the chip is less than about 200 μm, such as less than 100 μm, less than 50 μm, less than 20 μm, less than 10 μm, or smaller. For example, the linear dimension of a micro-LED may be as small as 6 μm, 5 μm, 4 μm, 2 μm, or smaller. Some micro-LEDs may have active regions (e.g., mesas) with a linear dimension (e.g., length or diameter) comparable to the minority carrier diffusion length. However, the disclosure herein is not limited to micro-LEDs, and may also be applied to mini-LEDs. As used herein, the lateral linear size of a micro-LED may refer to the lateral linear dimension of the active region or the mesa structure of the micro-LED, such as the diameter or side of the mesa structure or the active region.

As used herein, the term “bonding” may refer to various methods for physically and/or electrically connecting two or more devices and/or wafers, such as adhesive bonding, metal-to-metal bonding, metal oxide bonding, wafer-to-wafer bonding, die-to-wafer bonding, hybrid bonding, soldering, under-bump metallization, and the like. For example, adhesive bonding may use a curable adhesive (e.g., an epoxy) to physically bond two or more devices and/or wafers through adhesion. Metal-to-metal bonding may include, for example, wire bonding or flip chip bonding using soldering interfaces (e.g., pads or balls), conductive adhesive, or welded joints between metals. Metal oxide bonding may form a metal and oxide pattern on each surface, bond the oxide sections together, and then bond the metal sections together to create a conductive path. Wafer-to-wafer bonding may bond two wafers (e.g., silicon wafers or other semiconductor wafers) without any intermediate layers and is based on chemical bonds between the surfaces of the two wafers. Wafer-to-wafer bonding may include wafer cleaning and other preprocessing, aligning and pre-bonding at room temperature, and annealing at elevated temperatures, such as about 250° C. or higher. Die-to-wafer bonding may use bumps on one wafer to align features of a pre-formed chip with drivers of a wafer. Hybrid bonding may include, for example, wafer cleaning, high-precision alignment of contacts of one wafer with contacts of another wafer, dielectric bonding of dielectric materials within the wafers at room temperature, and metal bonding of the contacts by annealing at, for example, 250-300° C. or higher. As used herein, the term “bump” may refer generically to a metal interconnect used or formed during bonding.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

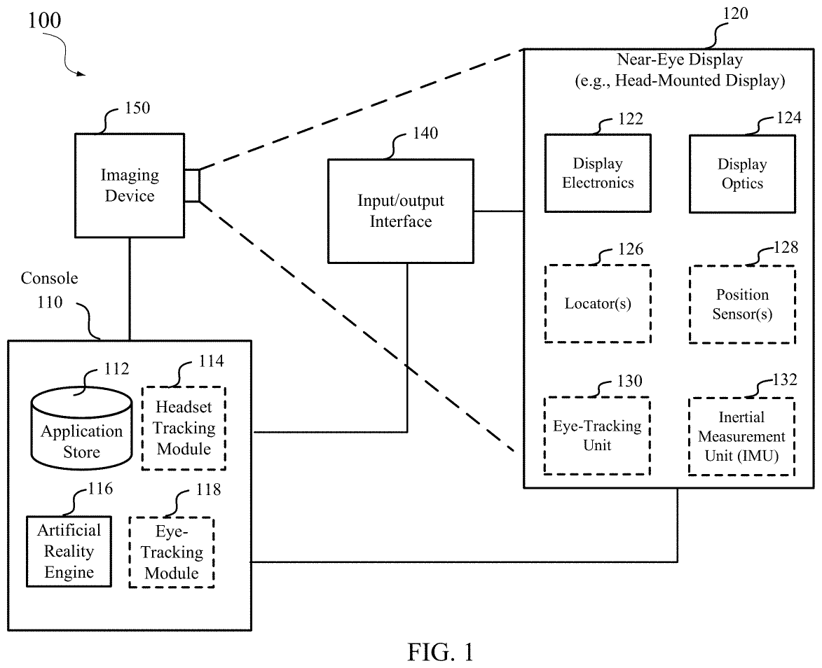

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

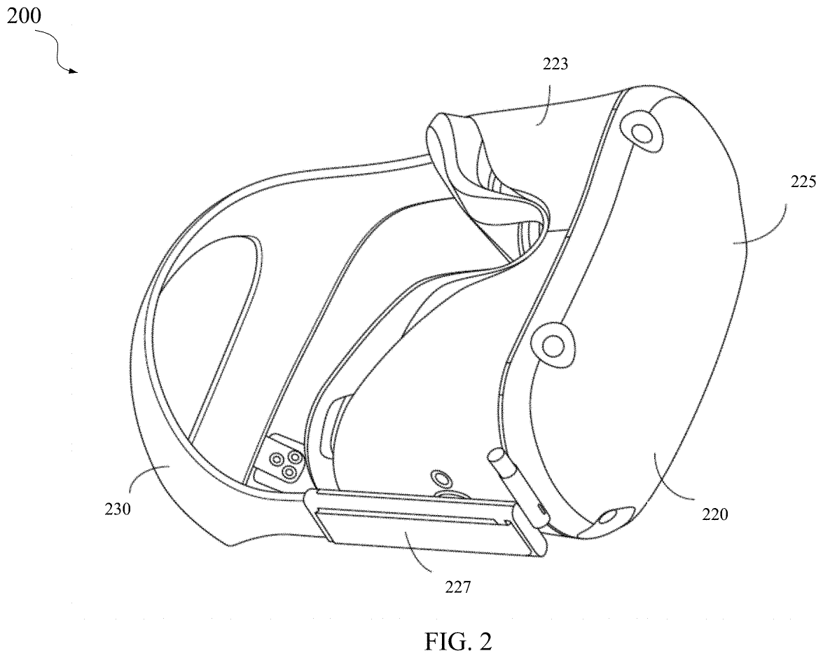

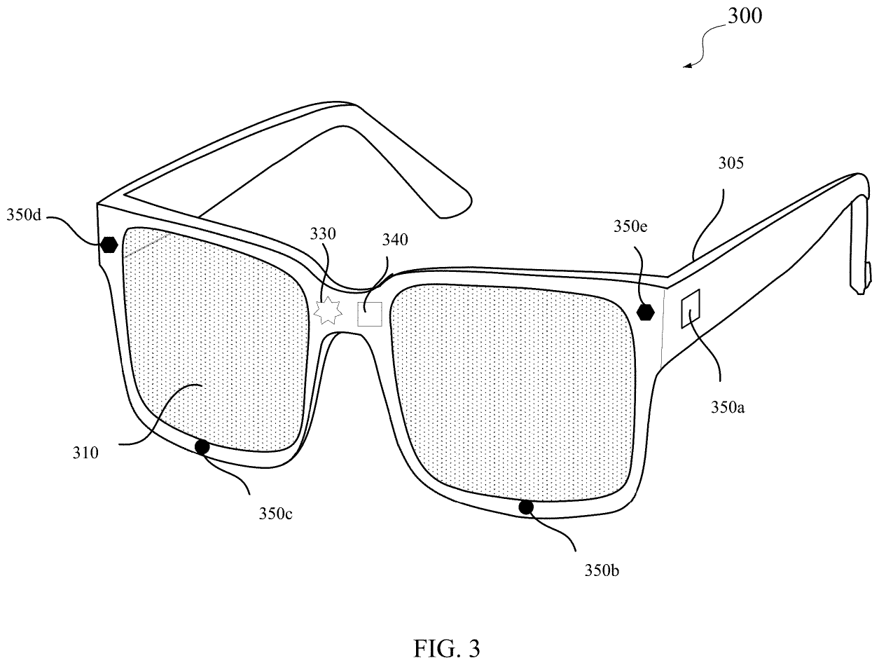

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

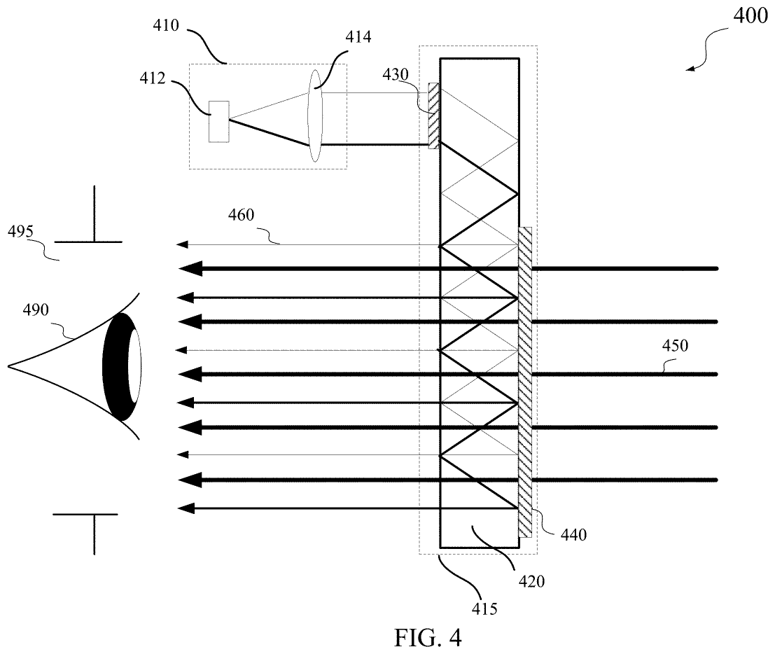

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

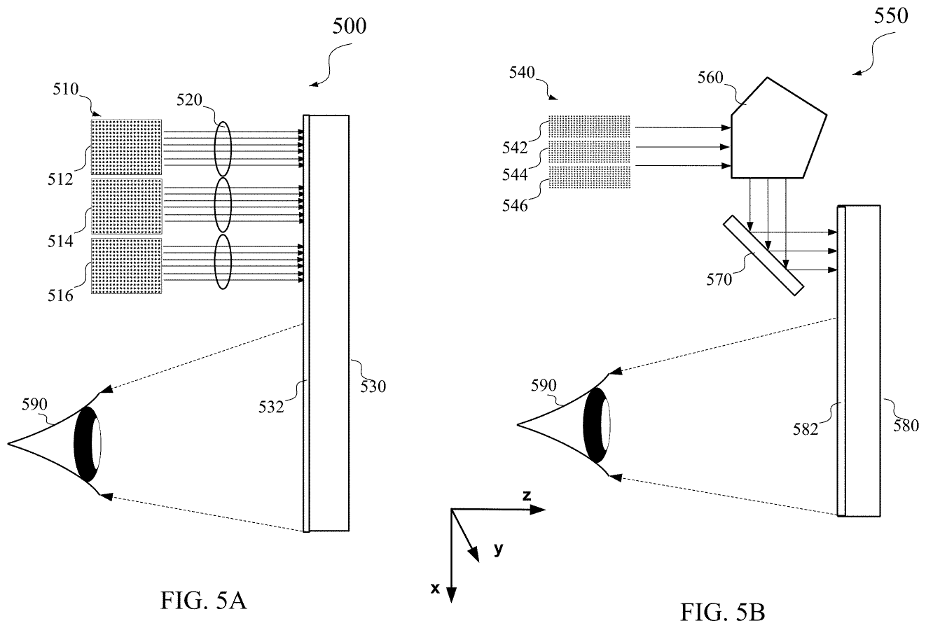

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

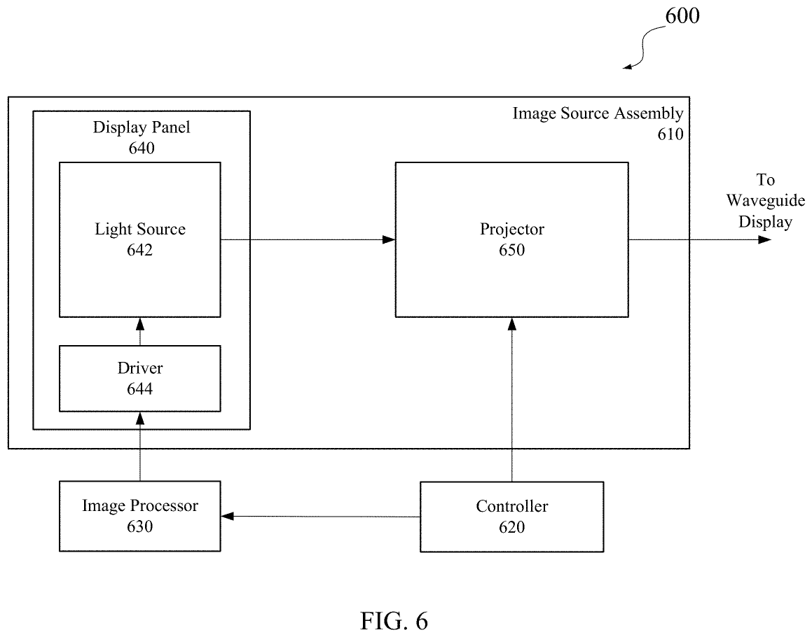

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a driver circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and driver circuit 644, image processor 630 may be a sub-unit of controller 620 or driver circuit 644 in other embodiments. In other words, in those embodiments, controller 620 or driver circuit 644 may perform various image processing functions of image processor 630. Image processor 630 may also be referred to as an image processing circuit.

In the example shown in FIG. 6, light source 642 may be driven by driver circuit 644, based on data or instructions (e.g., display and scanning instructions) sent from controller 620 or image processor 630. In one embodiment, driver circuit 644 may include a circuit panel that connects to and mechanically holds various light emitters of light source 642. Light source 642 may emit light in accordance with one or more illumination parameters that are set by the controller 620 and potentially adjusted by image processor 630 and driver circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

The overall efficiency of a photonic integrated circuit or a waveguide-based display (e.g., in augmented reality system 400 or NED device 500 or 550) may be a product of the efficiency of individual components and may also depend on how the components are connected. For example, the overall efficiency ηₜₒₜ of the waveguide-based display in augmented reality system 400 may depend on the light emitting efficiency of image source 412, the light coupling efficiency from image source 412 into combiner 415 by projector optics 414 and input coupler 430, and the output coupling efficiency of output coupler 440, and thus may be determined as:

ηₜₒₜ=η_{EQE}×ηᵢₙ×ηₒᵤₜ, (1)

where η_{EQE} is the external quantum efficiency of image source 412, Tᵢₙ is the in-coupling efficiency of light from image source 412 into the waveguide (e.g., substrate 420), and ηₒᵤₜ is the outcoupling efficiency of light from the waveguide towards the user's eye by output coupler 440. Thus, the overall efficiency ηₜₒₜ of the waveguide-based display can be improved by improving one or more of η_{EQE}, ηᵢₙ, and ηₒᵤₜ.

The optical coupler (e.g., input coupler 430 or coupler 532) that couples the emitted light from a light source to a waveguide may include, for example, a grating, a lens, a micro-lens, a prism. In some embodiments, light from a small light source (e.g., a micro-LED) can be directly (e.g., end-to-end) coupled from the light source to a waveguide, without using an optical coupler. In some embodiments, the optical coupler (e.g., a lens or a parabolic-shaped reflector) may be manufactured on the light source.

The light sources, image sources, or other displays described above may include one or more LEDs. For example, each pixel in a display may include three subpixels that include a red micro-LED, a green micro-LED, and a blue micro-LED. A semiconductor light emitting diode generally includes an active light emitting layer within multiple layers of semiconductor materials. The multiple layers of semiconductor materials may include different compound materials or a same base material with different dopants and/or different doping densities. For example, the multiple layers of semiconductor materials may generally include an n-type material layer, an active layer that may include hetero-structures (e.g., one or more quantum wells), and a p-type material layer. The multiple layers of semiconductor materials may be grown on a surface of a substrate having a certain orientation.

Photons can be generated in a semiconductor LED (e.g., a micro-LED) at a certain internal quantum efficiency through the recombination of electrons and holes within the active layer (e.g., including one or more semiconductor layers). The generated light may then be extracted from the LEDs in a particular direction or within a particular solid angle. The ratio between the number of emitted photons extracted from the LED and the number of electrons passing through the LED is referred to as the external quantum efficiency, which describes how efficiently the LED converts injected electrons to photons that are extracted from the device. The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device.

For LEDs, and in particular, micro-LEDs with reduced physical dimensions, improving the internal and external quantum efficiency can be challenging. In some embodiments, to increase the light extraction efficiency, a mesa that includes at least some of the layers of semiconductor materials may be formed.

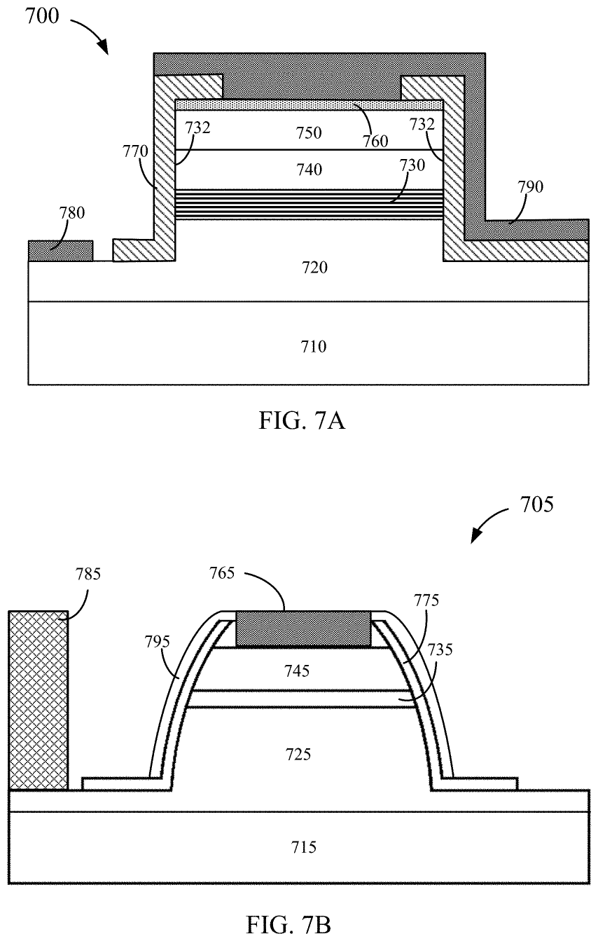

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlGaInP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlGaInP situated between a layer of p-type AlGaInP doped with zinc or magnesium and a layer of n-type AlGaInP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on mesa sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlGaInP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlGaInP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiNₓ) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across electrical contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlGaInP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

When the mesa structure is formed (e.g., etched), the facets of the mesa structure, such as mesa sidewalls 732, may include some imperfections, such as unsatisfied bonds, chemical contamination, and structural damages (e.g., when dry-etched), that may decrease the internal quantum efficiency of the LED. For example, at the facets, the atomic lattice structure of the semiconductor layers may come to an abrupt end, where some atoms of the semiconductor materials may lack neighbors to which bonds may be attached. This results in “dangling bonds,” which may be characterized by unpaired valence electrons. These dangling bonds create energy levels that otherwise would not exist within the bandgap of the semiconductor material, causing non-radiative electron-hole recombination at or near the facets of the mesa structure. Thus, these imperfections may become the recombination centers where electrons and holes may be confined until they combine non-radiatively.

As described above, the internal quantum efficiency is the proportion of the radiative electron-hole recombination in the active region that emits photons. The internal quantum efficiency of LEDs depends on the relative rates of competitive radiative (light producing) recombination and non-radiative (lossy) recombination that occur in the active region of the LEDs. Non-radiative recombination processes in the active region may include Shockley-Read-Hall (SRH) recombination at defect sites and eeh/ehh Auger recombination, which is a non-radiative process involving three carriers. The internal quantum efficiency of an LED may be determined by:

$$IQE = \frac{{BN}^{2}}{AN + {BN}^{2} + {CN}^{3}} , \qquad ( 2 )$$

where A, B and C are the rates of SRH recombination, bimolecular (radiative) recombination, and Auger recombination, respectively, and N is the charge-carrier density (i.e., charge-carrier concentration) in the active region.

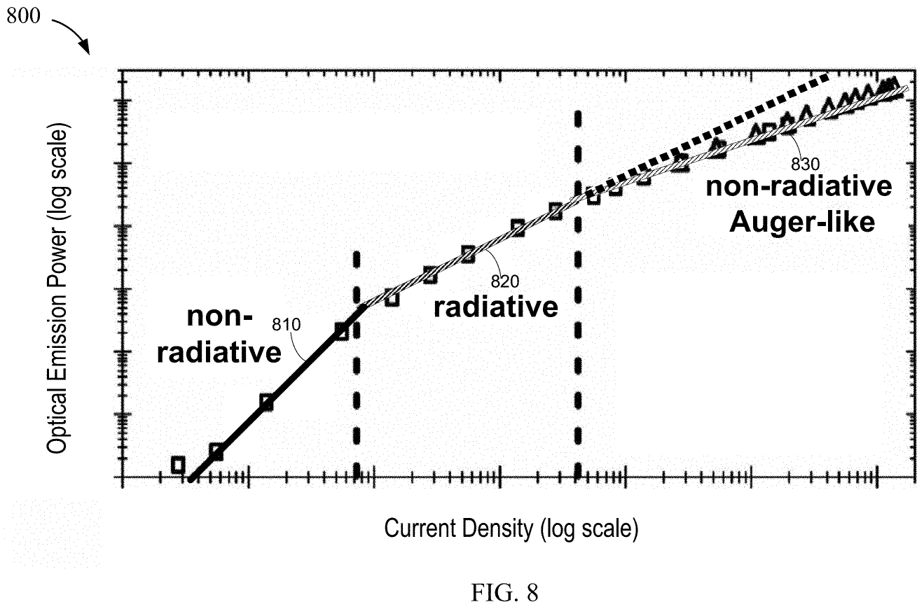

FIG. 8 illustrates the relationship between the optical emission power and the current density of a light emitting diode. As illustrated by a curve 810 in FIG. 8, the optical emission power of a micro-LED device may be low when the current density (and thus the charge carrier density N) is low, where the low external quantum efficiency may be caused by the relatively high non-radiative SRH recombination when the charge carrier density N is low according to equation (2). As the current density (and thus the charge carrier density N) increases, the optical emission power may increase as shown by a curve 820 in FIG. 8, because the radiative recombination may increase at a higher rate (∝N²) than the non-radiative SRH recombination (∝N) when the charge carrier density N is high according to equation (2). As the current density increases further, the optical emission power may increase at a slower rate as shown by a curve 830 in FIG. 8 and thus the external quantum efficiency may drop as well because, for example, the non-radiative Auger recombination may increase at a higher rate (∝N³) than the radiative recombination (∝N²) when the charge carrier density N is sufficiently high according to equation (2).

Auger recombination is a non-radiative process involving three carriers. Auger recombination may be a major cause of efficiency droop and may be direct or indirect. For example, direct Auger recombination occurs when an electron and a hole recombine, but instead of producing light, either an electron is raised higher into the conduction band or a hole is pushed deeper into the valence band. Auger recombination may be reduced to mitigate the efficiency droop by lowering the charge-carrier density N in the active region for a given injection current density J, which may be written as:

J=qd_{eff}(AN+BN²+CN³), (3)

where d_{eff} is the effective thickness of the active region. Thus, according to equation (3), the effect of the Auger recombination may be reduced and thus the IQE of the LED may be improved by reducing the charge-carrier density N for a given injection current density, which may be achieved by increasing the effective thickness of the active region d_{eff}. The effective thickness of the active region may be increased by, for example, growing multiple quantum wells (MQWs). Alternatively, an active region including a single thick double heterostructure (DH) may be used to increase the effective thickness of the active region.

One factor affecting the effective thickness of the active region is the presence of internal fields E_{qw} (e.g., strain-induced internal field) in the quantum wells. Internal fields E_{qw} may localize charge carriers and reduce the overlap integral between carrier wave functions, which may reduce the radiative efficiency of LEDs. Some LEDs including heterostructures (e.g., quantum wells) may have a strong internal strain-induced piezoelectric field in the carrier transport direction. The strain-induced internal field may cause the electron and hole energy levels to shift (thus changing the bandgap) and cause the electrons and holes to shift to opposite sides of a quantum well, thereby decreasing the spatial electron-hole overlap and reducing the radiative recombination efficiency and thus the internal quantum efficiency of the LED.

While the Auger recombination due to a high current density (and high charge carrier density) may be an intrinsic process depending on material properties, non-radiative SRH recombination depends on the characteristics and the quality of material, such as the defect density in the active region. As described above with respect to FIGS. 7A and 7B, LEDs may be fabricated by etching a mesa structure into the active emitting layers to confine carriers within the injection area of the device and to expose the n-type material beneath the active emitting layers for electrical contact. Etching the mesa structures may lead to the formation of mesa sidewalls that are orthogonal to the growth plane. As described above, due to the etching, the active region in proximity to the exposed sidewalls may have a higher density of defects, such as dislocations, pores, grain boundaries, vacancies, inclusion of precipitates, and the like. The defects may introduce energy states having deep or shallow energy levels in the bandgap. Carriers may be trapped by these energy states until they combine non-radiatively. Therefore, the active region in proximity to the exposed sidewalls may have a higher rate of SRH recombination than the bulk region that is far from the sidewalls.

Parameters that may affect the impact on the LED efficiency by the non-radiative surface recombination may include, for example, the surface recombination velocity (SRV) S, the carrier diffusion coefficient (diffusivity) D, and the carrier lifetime r. The high recombination rate in the vicinity of the sidewall surfaces due to the high defect density may depend on the number of excess carriers (in particular, the minority carriers) in the region. The high recombination rate may deplete the carriers in the region. The depletion of the carriers in the region may cause carriers to diffuse to the region from surrounding regions with higher carrier concentrations. Thus, the amount of surface recombination may be limited by the surface recombination velocity Sat which the carriers move to the regions near the sidewall surfaces. The carrier lifetime τ is the average time that a carrier can spend in an excited state after the electron-hole generation before it recombines with another carrier. The carrier lifetime ti generally depends on the carrier concentration and the recombination rate in the active region. The carrier diffusion coefficient (diffusivity) D of the material and the carrier lifetime r may determine the carrier diffusion length L=\sqrt{D×τ}, which is the average distance a carrier can travel from the point of generation until it recombines. The carrier diffusion length L characterizes the width of the region that is adjacent to a sidewall surface of the active region and where the contribution of surface recombination to the carrier losses is significant. Charge carriers injected or diffused into the regions that are within a minority carrier diffusion length from the sidewall surfaced may be subject to the higher SRH recombination rate.

A higher current density (e.g., in units of amps/cm²) may associated with a lower surface recombination velocity as the surface defects may be more and more saturated at higher carrier densities. Thus, the surface recombination velocity may be reduced by increasing the current density. In addition, the diffusion length of a given material may vary with the current density at which the device is operated. However, LEDs generally may not be operated at high current densities. Increasing the current injection may also cause the efficiencies of the micro-LEDs to drop due to the higher Auger recombination rate and the lower conversion efficiency at the higher temperature caused by self-heating at the higher current density.

For traditional, broad area LEDs used in lighting and backlighting applications (e.g., with an about 0.1 mm² to about 1 mm² lateral device area), the sidewall surfaces are at the far ends of the devices. The devices can be designed such that little or no current is injected into regions within a minority carrier diffusion length of the mesa sidewalls, and thus the sidewall surface area to volume ratio and the overall rate of SRH recombination may be low. However, in micro-LEDs, as the size of the LED is reduced to a value comparable to or having a same order of magnitude as the minority carrier diffusion length, the increased surface area to volume ratio may lead to a high carrier surface recombination rate, because a greater proportion of the total active region may fall within the minority carrier diffusion length from the LED sidewall surface. Therefore, more injected carriers are subjected to the higher SRH recombination rate. This can cause the leakage current of the LED to increase and the efficiency of the LED to decrease as the size of the LED decreases, and/or cause the peak efficiency operating current to increase as the size of the LED decreases. For example, for a first LED with a 100 μm×100 μm×2 μm mesa, the side-wall surface area to volume ratio may be about 0.04. However, for a second LED with a 5 μm×5 μm×2 μm mesa, the side wall surface area to volume ratio may be about 0.8, which is about 20 times higher than the first LED. Thus, with a similar surface defect density, the SRH recombination coefficient of the second LED may be about 20 times higher as well. Therefore, the efficiency of the second LED may be reduced significantly.

AlGaInP material may have a high surface recombination velocity and minority carrier diffusion length than some other light emission materials, such as III-nitride materials. For example, red AlGaInP LEDs may generally operate at a reduced carrier concentration (e.g., about 10¹⁷ to 10¹⁸ cm⁻³), and thus may have a relatively long carrier lifetime r. The carrier diffusivity D in the active region in the undoped quantum wells of red AlGaInP LEDs may also be rather large. As a result, the carrier diffusion length L=\sqrt{D×τ} can be, for example, about 10-25 μm or longer in some devices. In addition, the surface recombination velocity of AlGaInP material may be an order of magnitude higher than the surface recombination velocities of III-nitride materials. Thus, compared with LED made of III-nitride materials (e.g., blue and green LEDs made of GaN), the internal and external quantum efficiencies of AlGaInP-based red LEDs can drop even more significantly as the device size decreases.

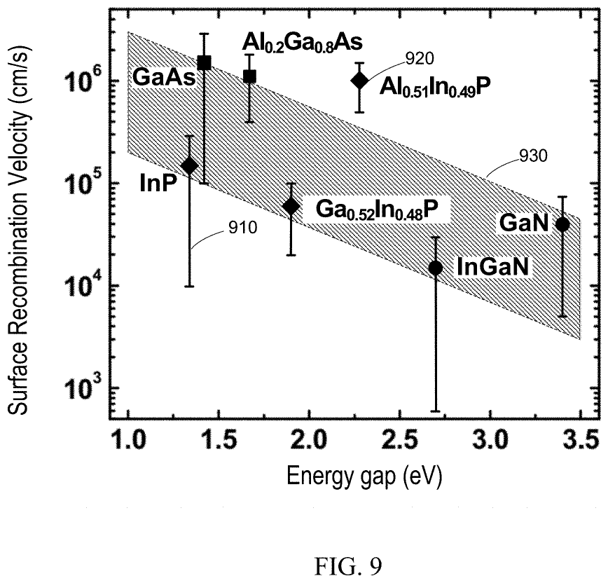

FIG. 9 illustrates surface recombination velocities of various III-V semiconductor materials. Bars 910 in FIG. 9 show the ranges of reported SRV values of the III-V semiconductor materials, whereas symbols 920 on bars 910 indicate the common or averaged SRVs. A box 930 shows a general trend of the variation of the surface recombination velocity with the change of the material bandgap. As illustrated in FIG. 9, the SRV is high in GaAs (e.g., about 10⁶ cm/s) compared to InP (e.g., about 10⁵ cm/s) or GaN (e.g., less than about 0.5×10⁵ cm/s). The surface recombination velocity of AlGaInP material (e.g., about 10⁶ cm/s) may be at least an order of magnitude higher than the surface recombination velocity of III-nitride materials (e.g., <10⁵ cm/s). In addition, in Al-containing alloys, such as AlGaInP, SRVs may scale appreciably with the Al fraction. For example, the SRV may increase from about 10⁵ cm/s for (Al_{0.1}Ga_{0.9})_{0.5}In_{0.5}P to about 10⁶ cm/s for Al_{0.51}In_{0.49}P.

In addition, nitride LEDs can operate at non-equilibrium carrier concentrations much higher than phosphide LEDs, which results in considerably shorter carrier lifetime in nitride LEDs. Therefore, the carrier diffusion lengths in the active regions of III-nitride LEDs are considerably shorter than the carrier diffusion lengths in phosphide LEDs. As such, phosphide LEDs, such as AlGaInP-based red micro-LEDs, may have both higher SRVs and longer carrier diffusion lengths, and thus may have much higher surface recombination and efficiency reduction, than III-nitride LEDs.

Because the minority carrier (lateral) diffusion length in the active material of red micro-LED devices is much higher than, for example, the minority carrier (lateral) diffusion lengths in GaN-based material systems, red/NIR light-emitting devices (e.g. LEDs/VCSELs) based on AlGaInP, AlGaAs, or other material systems may suffer from high surface loss, especially for devices with lateral sizes less than about 50 μm, such as less than about 20 μm or less than about 10 μm, leading to much lower efficiencies (e.g., EQEs) due to enhanced surface losses.

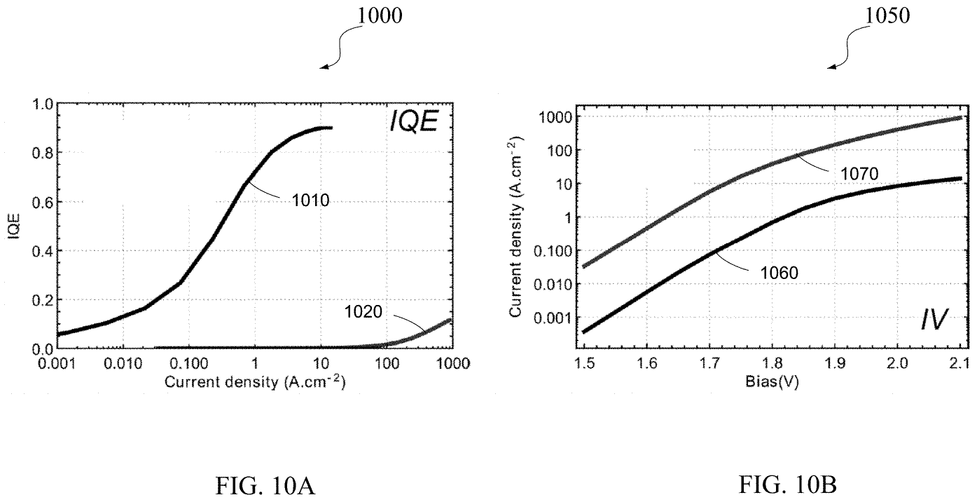

FIG. 10A includes a diagram 1000 illustrating internal quantum efficiencies of examples of AlGaInP red micro-LEDs of different sizes as a function of the driving current density. A curve 1010 in diagram 1000 shows the IQE of an AlGaInP red micro-LED with a lateral linear size (e.g., a diameter or side of the active region or the mesa) about 200 μm as a function of the current density. A curve 1020 shows the IQE of an AlGaInP red micro-LED with a lateral linear size (e.g., a diameter or side of the active region or the mesa structure) about 2 μm as a function of the current density. FIG. 10 shows that the larger micro-LED exhibits much higher IQEs than the smaller micro-LED at the same current density. Curves 1010 and 1020 in FIG. 10 also show that, for micro-LEDs with smaller linear sizes, the current densities to achieve the peak efficiencies may also need to be much higher.

FIG. 10B includes a diagram 1050 illustrating current densities of examples of AlGaInP red micro-LEDs of different sizes at different bias voltages. A curve 1060 in diagram 1050 shows the current density of the AlGaInP red micro-LED with the lateral linear size about 200 μm as a function of the forward bias voltage. A curve 1070 shows the current density of the AlGaInP red micro-LED with the lateral linear size about 2 μm as a function of the forward bias voltage.

The non-radiative surface recombination described above may be reduced by, for example, passivating the mesa surface with a suitable dielectric material, such as SiO₂, SiNₓ, or Al₂O₃. The SRV may be reduced by etching away highly defective surface material using a chemical treatment. Alternatively or in addition, surface recombination may be reduced by decreasing the lateral carrier mobility. For example, the lateral carrier mobility may be decreased by using ion implantation to disrupt the semiconductor lattice outside of a central portion of the micro-LED. Alternatively or additionally, the lateral carrier mobility may be decreased by using quantum well intermixing to change the composition of areas of the semiconductor layer outside of the central portion of the micro-LED. Despite these efforts to reduce surface recombination, when the micro-LED mesa size reduces, the efficiency of the micro-LED may drastically decrease and the peak efficiency operating current density may increase, mainly due to the loss caused by non-radiative surface recombination at the mesa sidewalls.

In large micro-LEDs, the quantum efficiencies (e.g., as determined by measuring the photoluminescence) at low current densities (e.g., less than about 1 A/cm², such as about few tens mA/cm²) may be improved by doping in the active region. However, the dopants in the active region can form defects and thus can reduce the efficiencies of the devices during normal operations, where the current densities may be much higher in order to achieve a high output power. For example, the normal operating current density may be greater than about 1 A/cm², greater than about 10 A/cm², or greater than about 100 A/cm². Therefore, doping in the active regions (e.g., in the barrier layers) is generally not desired or performed for micro-LEDs operating at high current densities.

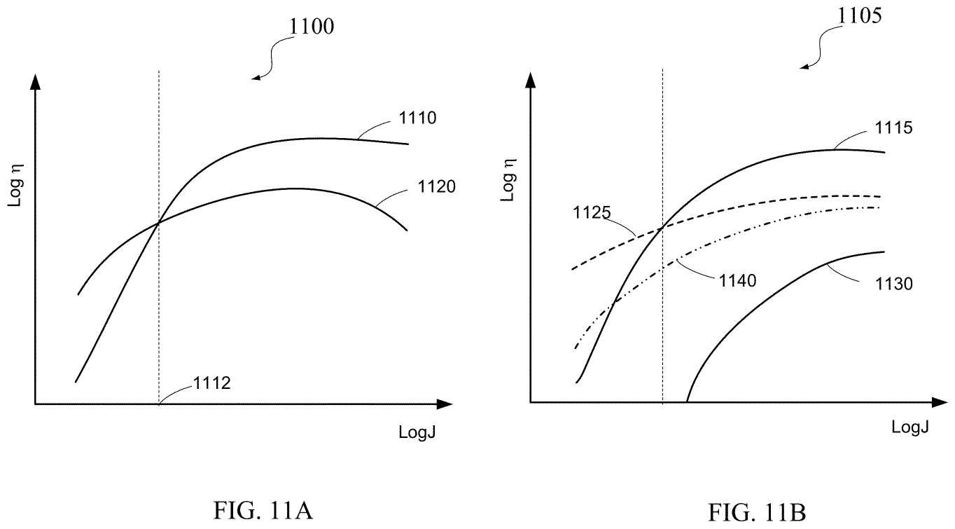

FIG. 11A illustrates the relationship between the external quantum efficiency and the current density for two micro-LEDs having the same size, where the first micro-LED is not intentionally doped in the active region while the second micro-LED is intentionally doped in the active region. The two micro-LEDs may have a linear lateral size greater than about 20 μm, such as greater than about 30 μm or greater than about 50 μm. In the illustrated example, a curve 1110 shows the external quantum efficiency of the first micro-LED as a function of the current density, while a curve 1120 shows the external quantum efficiency of the second micro-LED as a function of the current density. Curves 1110 and 1120 show that, at a lower current density (e.g., tens or hundreds of mA/cm²), the quantum efficiency of the second micro-LED (with doping in the active region) is higher than that of the first micro-LED (without doping int the active region). However, to generate light with a sufficiently high power for many applications (e.g., displaying images in AR/VR systems), the micro-LED may need to operate at much higher current densities, such as greater than 10 A/cm², greater than about 100 A/cm², or higher. As shown in FIG. 11A, when the current density is greater than a certain value 1112, such as about 1 A/cm², the quantum efficiency of the second micro-LED may be much lower than that of the first micro-LED. Therefore, for larger micro-LEDs, doping the active region may not help to improve the efficiencies of the micro-LEDs during normal operations.

In the present disclosure, it is determined that, for devices with lateral sizes less than certain threshold values, doping in the active regions can also significantly improve the quantum efficiency at the device's normal operation conditions, for example, with current densities greater than about 10 A/cm², due to the suppression of surface losses. The sizes of small micro-LEDs with doping in the active region and having improved internal and external quantum efficiencies may be, for example, less than about 20 μm, less than about 10 μm, or less than about 8 μm, which may be different for different doping densities and/or different current densities. It is also determined that, for a small micro-LED with doping in the active region that includes a MQW structure, the radiative recombination may mainly occur in one quantum well, such as the quantum well that is closest to the p-type semiconductor region that injects holes into the active region.

FIG. 11B illustrates external quantum efficiencies of examples of micro-LEDs of different sizes and with or without doping in the active region as a function of the current density. In FIG. 11B, a curve 1115 shows the external quantum efficiency of a first micro-LED as a function of the current density, where the first micro-LED may have a lateral size of, for example, about 30 μm, and the active region of the first micro-LED may not be intentionally doped. A curve 1125 shows the external quantum efficiency of a second micro-LED as a function of the current density, where the second micro-LED may have a lateral size of, for example, about 30 μm, and the active region of the second micro-LED may be intentionally doped. As described above with respect to FIG. 11A, the second micro-LED may have higher efficiencies at low current density than the first micro-LED, but may have much lower efficiencies at normal operation conditions where high current densities may be needed to generate light with a sufficiently high power.

FIG. 11B also includes a curve 1130 showing the external quantum efficiency of a third micro-LED as a function of the current density, where the third micro-LED may have a lateral size less than about 10 μm, such as about 2 μm, and the active region of the third micro-LED may not be intentionally doped. A curve 1140 in FIG. 11B shows the external quantum efficiency of a fourth micro-LED as a function of the current density, where the fourth micro-LED may have a lateral size of, for example, 2 μm, and the active region of the fourth micro-LED may be intentionally doped. As shown by curves 1130 and 1140, the fourth micro-LED may have higher efficiencies than the third micro-LED at both low current densities and high current densities (e.g., at the device's normal operation conditions).

Thus, according to certain embodiments, the active region of small red micro-LEDs (e.g., with phosphide materials, such as AlGaInP, for an emission wavelength greater than about 590 nm) with pixel sizes less than, for example, about 20 or about 10 μm, may be intentionally doped during the epitaxial growth to improve the EQEs of the micro-LEDs at high current densities, such as about 10 A/cm². Examples of the dopants include selenium, silicon, or tellurium, which may be less likely to diffuse into the quantum wells during the epitaxial growth. The dopant atomic concentration can range from, for example, about 1×10¹⁷/cm³ to about 5×10¹⁸/cm³ or about 1×10¹⁹/cm³.

In some embodiments, the dopants may only be introduced in one or more but not all barrier layers, to reduce the potential impact of non-radiative recombination mechanisms associated with dopant-related defects or defect-complexes. In one example, only the top barrier on the p-side is doped. In some embodiments, the doped one or more barrier layers may include an additional setback layer between the doping region and the quantum well to further improve the efficiency due to the reduction of non-radiative recombination.

In some embodiments, the small micro-LEDs may include only one quantum well. One or both barrier layers of the quantum well may be doped with, for example, silicon selenium, or tellurium. The doping can be in the whole barrier layer or may be in a middle portion of a barrier layer.

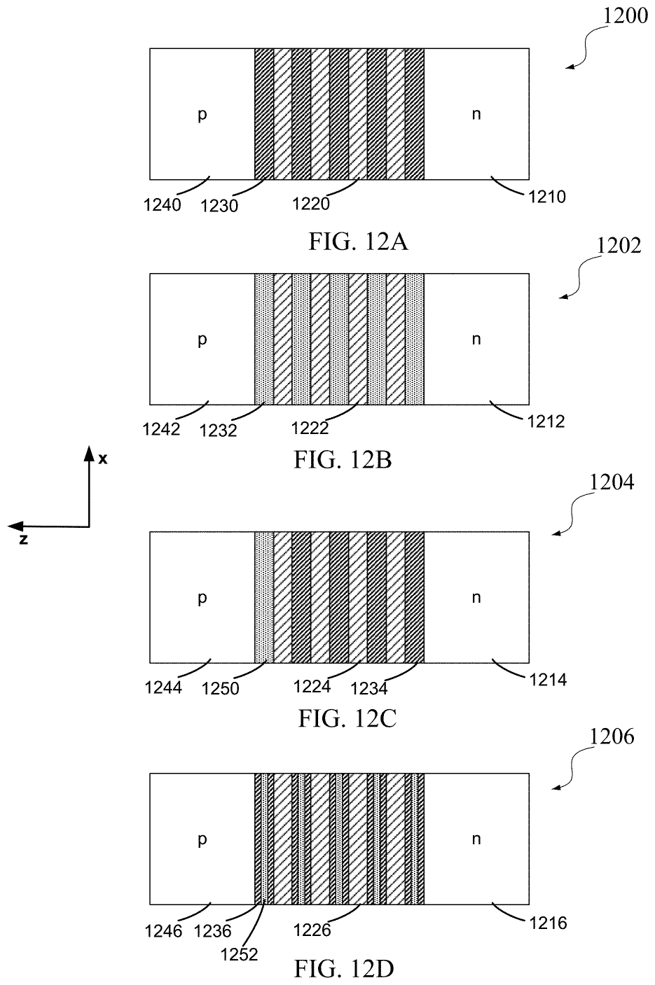

FIG. 12A illustrates an example of a red micro-LED 1200 with no doping in the active region. In the illustrated example, red micro-LED 1200 may include an n-type semiconductor layer 1210, a p-type semiconductor layer 1240, and an active region between n-type semiconductor layer 1210 and p-type semiconductor layer 1240. The active region may include a MQW structure that includes a plurality of quantum well layers 1220 and a plurality of barrier layers 1230, where each quantum well layer 1220 may be sandwiched by two barrier layers 1230. In one example, the quantum well layers may include GaInP, while the barrier layers may include AlGaInP. In another example, the quantum well layers may include GaAs, while the barrier layer may include AlGaAs. In red micro-LED 1200, barrier layers 1230 may not be intentionally doped.

FIG. 12B illustrates an example of a red micro-LED 1202 with doping in the barrier layers of an MQW structure according to certain embodiments. In the example shown in FIG. 12B, red micro-LED 1202 may include an n-type semiconductor layer 1212, a p-type semiconductor layer 1242, and an active region between n-type semiconductor layer 1212 and p-type semiconductor layer 1242. The active region may include the MQW structure that includes a plurality of quantum well layers 1222 and a plurality of barrier layers 1232, where each quantum well layer 1222 may be sandwiched by two barrier layers 1232. In one example, the quantum well layers may include GaInP, while the barrier layers may include AlGaInP. In another example, the quantum well layers may include GaAs, while the barrier layer may include AlGaAs. Even though FIG. 12B shows a MQW structure having four quantum well layers, red micro-LED 1202 may have fewer or more quantum well layers, such as from 1 to 9 quantum well layers.

Red micro-LED 1202 may have a linear dimension in the x-direction less than about 20 μm, such as less than about 10 μm. All barrier layers 1232 of red micro-LED 1202 may be intentionally doped with, for example, silicon, selenium, or tellurium. The doping density may be, for example, between about 1×10¹⁷/cm³ to about 5×10¹⁸/cm³ or to about 1×10¹⁹/cm³. In normal operation conditions, carriers may be injected into red micro-LED 1202 at a current density greater than 1 A/cm², such as greater than about 10 A/cm² or higher.

FIG. 12C illustrates an example of a red micro-LED 1204 with doping in one or more but not all barrier layers of an MQW structure according to certain embodiments. In the example shown in FIG. 12C, red micro-LED 1204 may include an n-type semiconductor layer 1214, a p-type semiconductor layer 1244, and an active region between n-type semiconductor layer 1214 and p-type semiconductor layer 1244. The active region may include the MQW structure that includes a plurality of quantum well layers 1224 and a plurality of barrier layers 1234, where each quantum well layer 1224 may be sandwiched by two barrier layers 1234. In one example, the quantum well layers may include GaInP, while the barrier layers may include AlGaInP. In another example, the quantum well layers may include GaAs, while the barrier layer may include AlGaAs. Even though FIG. 12C shows the MQW structure having four quantum well layers, red micro-LED 1204 may have fewer or more quantum well layers, such as from 1 to 9 quantum well layers.

Red micro-LED 1204 may have a linear dimension in the x-direction less than about 20 μm, such as less than about 10 μm. A barrier layer 1250 of red micro-LED 1202 may be intentionally doped with, for example, silicon, selenium, or tellurium. In the illustrated example, barrier layer 1250 may be the barrier layer that is closest to p-type semiconductor layer 1244. The doping density may be, for example, between about 1×10¹⁷/cm³ to about 5×10¹⁸/cm³ or to about 1×10¹⁹/cm³. In normal operation conditions, carriers may be injected into red micro-LED 1204 at a current density greater than 1 A/cm², such as greater than about 10 A/cm² or higher.

FIG. 12D illustrates an example of a red micro-LED 1206 with doping in the middle portion of each barrier layer of an MWQ structure according to certain embodiments. In the example shown in FIG. 12D, red micro-LED 1206 may include an n-type semiconductor layer 1216, a p-type semiconductor layer 1246, and an active region between n-type semiconductor layer 1216 and p-type semiconductor layer 1246. The active region may include the MQW structure that includes a plurality of quantum well layers 1226 and a plurality of barrier layers 1236, where each quantum well layer 1226 may be sandwiched by two barrier layers 1236. In one example, the quantum well layers may include GaInP, while the barrier layers may include AlGaInP. In another example, the quantum well layers may include GaAs, while the barrier layer may include AlGaAs. Even though FIG. 12D shows the MQW structure having four quantum well layers, red micro-LED 1206 may have fewer or more quantum well layers, such as from 1 to 9 quantum well layers.

Red micro-LED 1206 may have a linear dimension in the x-direction less than about 20 μm, such as less than about 10 μm. Each barrier layer 1236 of red micro-LED 1206 may be intentionally doped with, for example, silicon, selenium, or tellurium. In the illustrated example, the doping may be in a middle portion 1252 of each barrier layer 1236 and may be introduced during the epitaxial growth of the semiconductor layers of various thicknesses. The doping density may be, for example, between about 1×10¹⁷/cm³ to about 5×10¹⁸/cm³ or to about 1×10¹⁹/cm³. In normal operation conditions, carriers may be injected into red micro-LED 1206 at a current density greater than 1 A/cm², such as greater than about 10 A/cm² or higher.

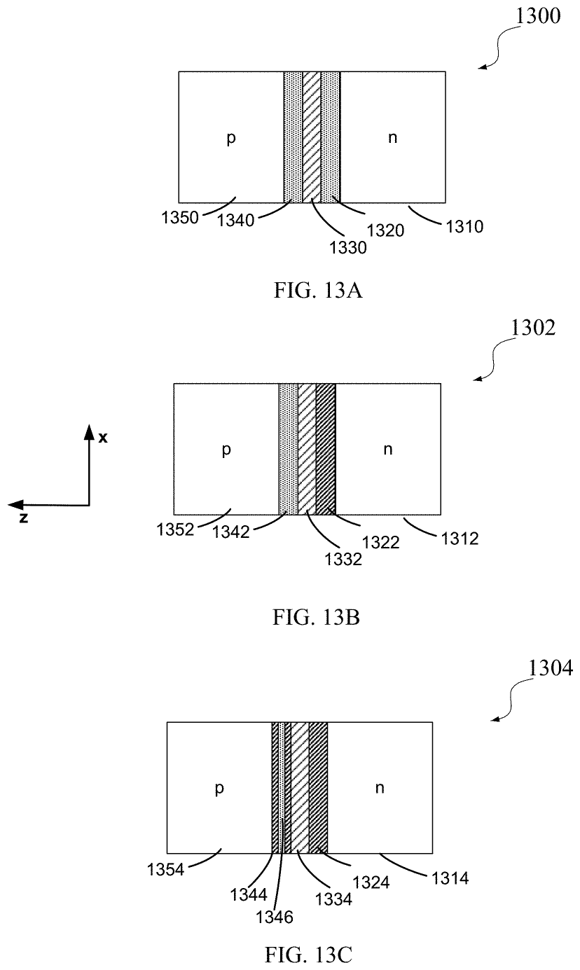

FIG. 13A illustrates an example of a red micro-LED 1300 with doping in the barrier layers of a quantum well structure according to certain embodiments. In the example shown in FIG. 13A, red micro-LED 1300 may include an n-type semiconductor layer 1310, a p-type semiconductor layer 1350, and an active region between n-type semiconductor layer 1310 and p-type semiconductor layer 1350. The active region may include a quantum well layer 1330 sandwiched by barrier layers 1320 and 1340. Quantum well layer 1330 may include, for example, GaInP or GaAs, while barrier layers 1320 and 1340 may include, for example, AlGaInP or AlGaAs. Red micro-LED 1300 may have a linear dimension in the x-direction less than about 20 μm, such as less than about 10 μm. Barrier layers 1320 and 1340 may be intentionally doped with, for example, silicon, selenium, or tellurium, during the epitaxial growth. The doping density may be, for example, between about 1×10¹⁷/cm³ to about 5×10¹⁸/cm³ or to about 1×10¹⁹/cm³. In normal operation conditions, carriers may be injected into red micro-LED 1300 at a current density greater than 1 A/cm², such as greater than about 10 A/cm².

FIG. 13B illustrates an example of a red micro-LED 1302 with doping in a barrier layer of a quantum well structure according to certain embodiments. In the example shown in FIG. 13B, red micro-LED 1302 may include an n-type semiconductor layer 1312, a p-type semiconductor layer 1352, and an active region between n-type semiconductor layer 1312 and p-type semiconductor layer 1352. The active region may include a quantum well layer 1332 sandwiched by barrier layers 1322 and 1342. Quantum well layer 1332 may include, for example, GaInP or GaAs, while barrier layers 1322 and 1342 may include, for example, AlGaInP or AlGaAs. Red micro-LED 1302 may have a linear dimension in the x-direction less than 20 μm, such as less than about 10 μm. Barrier layer 1342 may be intentionally doped with, for example, silicon, selenium, or tellurium, during the epitaxial growth. The doping density may be, for example, between about 1×10¹⁷/cm³ to about 5×10¹⁸/cm³. In normal operation conditions, carriers may be injected into red micro-LED 1302 at a current density greater than 1 A/cm², such as greater than about 10 A/cm².

FIG. 13C illustrates an example of a red micro-LED 1304 with doping in the middle portion of a barrier layer of a quantum well structure according to certain embodiments. In the example shown in FIG. 13C, red micro-LED 1304 may include an n-type semiconductor layer 1314, a p-type semiconductor layer 1354, and an active region between n-type semiconductor layer 1314 and p-type semiconductor layer 1354. The active region may include a quantum well layer 1334 sandwiched by barrier layers 1324 and 1344. Quantum well layer 1334 may include, for example, GaInP or GaAs, while barrier layers 1324 and 1344 may include, for example, AlGaInP or AlGaAs. Red micro-LED 1302 may have a linear dimension in the x-direction less than about 20 μm, such as less than about 10 μm. A middle portion 1346 of barrier layer 1344 may be intentionally doped with, for example, silicon, selenium, or tellurium, during the epitaxial growth. The doping density may be, for example, between about 1×10¹⁷/cm³ to about 5×10¹⁸/cm³ or to about 1×10¹⁹/cm³. Under normal operation conditions, carriers may be injected into red micro-LED 1304 at a current density greater than 1 A/cm², such as greater than about 10 A/cm².

Even though not shown in FIGS. 12A-13C, in some embodiments, there may be an intermediate layer between a quantum well and a neighboring barrier layer. The intermediate layer may be formed in the epitaxial growing process, for example, during the transition from the quantum well growth to the barrier layer growth or during the transition from the barrier layer growth to the quantum well growth.

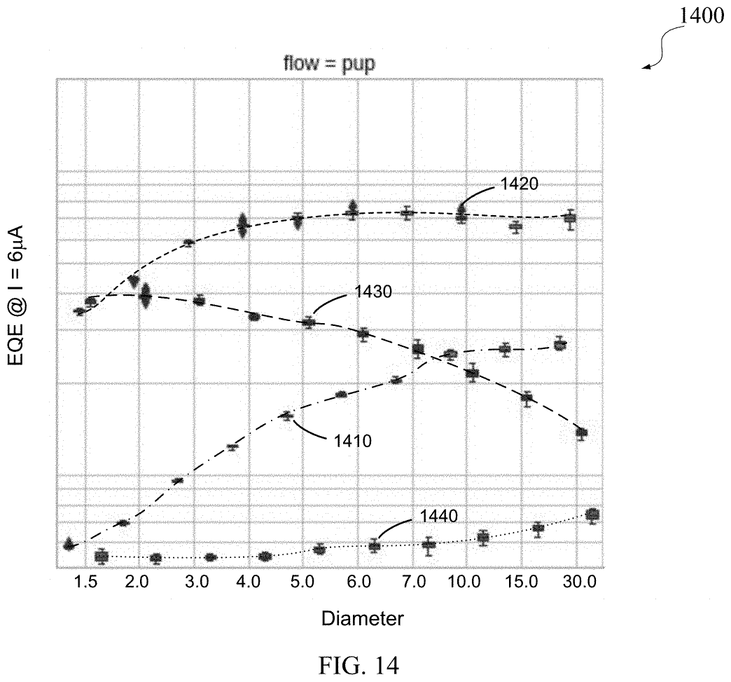

FIG. 14 includes a diagram 1400 illustrating external quantum efficiencies of examples of micro-LEDs having different sizes and different doping recipes in the active regions at a same total driving current, such as about 6 μA. Thus, the micro-LEDs with diameters less than about 30 μm may have different high current densities in the active regions. A curve 1410 in FIG. 14 shows the external quantum efficiencies of micro-LEDs having different sizes and without doping in the active regions. A curve 1420 in FIG. 14 shows the external quantum efficiencies of micro-LEDs having different sizes and with silicon doping in the barrier layers of the active regions, where the doping density is about 1×10¹⁸/cm³. A curve 1430 in FIG. 14 shows the external quantum efficiencies of micro-LEDs having different sizes and with silicon doping in the barrier layers of the active regions, where the doping density is about 4×10¹⁸/cm³. A curve 1440 in FIG. 14 shows the external quantum efficiencies of micro-LEDs having different sizes and with magnesium doping in the barrier layers of the active regions.

FIG. 14 shows that, for small micro-LEDs, such as micro-LEDs with diameters less than 30 μm, the EQEs of micro-LEDs with a silicon doping density at about 1×10¹⁸/cm³ in the barrier layers may be much higher than the EQEs of micro-LEDs without doping in the active region, when the driving current is the same. With a higher silicon doping density (e.g., 4×10¹⁸/cm³) in the barrier layers, EQEs of micro-LEDs having small sizes (e.g., smaller than about 10 μm) may be higher than the EQEs of micro-LEDs having similar sizes but without doping in the active region, when the driving current is the same. For small micro-LEDs, the EQEs of micro-LEDs with Mg doping in the barrier layers may be much lower than the EQEs of micro-LEDs without doping in the active region, when the driving current is the same. Thus, the effectiveness of the doping in the active region may depend on the doping material, the doping density, the size of the micro-LED (e.g., the lateral size of the active region or the mesa structure), and/or the current density in the active region.

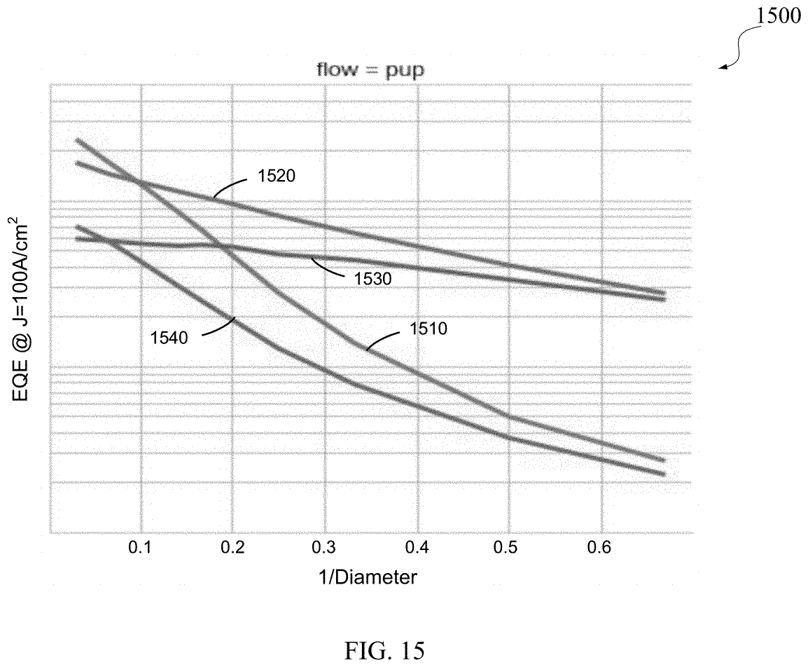

FIG. 15 includes a diagram 1500 illustrating external quantum efficiencies of examples of micro-LEDs having different sizes and different doping recipes in the active regions at a same injected current density. In the examples shown in FIG. 15, the injected current density for the micro-LEDs is about 100 A/cm². A curve 1510 in FIG. 15 shows the external quantum efficiencies of micro-LEDs having different sizes and without doping in the active regions at the same current density. A curve 1520 in FIG. 15 shows the external quantum efficiencies of micro-LEDs having different sizes and with silicon doping in the barrier layers of the active regions, where the doping density is about 1×10¹⁸/cm³. A curve 1530 in FIG. 15 shows the external quantum efficiencies of micro-LEDs having different sizes and with silicon doping in the barrier layers of the active regions, where the doping density is about 4×10¹⁸/cm³. A curve 1540 in FIG. 15 shows the external quantum efficiencies of micro-LEDs having different sizes and with magnesium doping in the barrier layers of the active regions.

FIG. 15 shows that, for small micro-LEDs, such as micro-LEDs with diameters less than about 10 μm, the EQEs of the micro-LEDs with a silicon doping density at about 1×10¹⁸/cm³ in the barrier layers may be higher than the EQEs of micro-LEDs having similar sizes but without doping in the active region, when the injected current density is the same. The EQE improvement may increase as the size of the micro-LED decreases. With a higher silicon doping density (e.g., about 4×10¹⁸/cm³) in the barrier layers, the EQEs of the micro-LEDs having small sizes (e.g., smaller than about 6 μm) may be higher than the EQEs of micro-LEDs having similar sizes but without doping in the active region, when the current density is the same. The EQE improvement may increase as the size of the micro-LED decreases. For small micro-LEDs, the EQEs of micro-LEDs with Mg doping in the barrier layers may be much lower than the EQEs of micro-LEDs of similar sizes but without doping in the active region, when the current density is about the same. Thus, FIG. 15 also shows that the effectiveness of the doping in the active region at a certain current density may depend on the doping material, the doping density, and the size of the micro-LED (e.g., the lateral size of the active region).

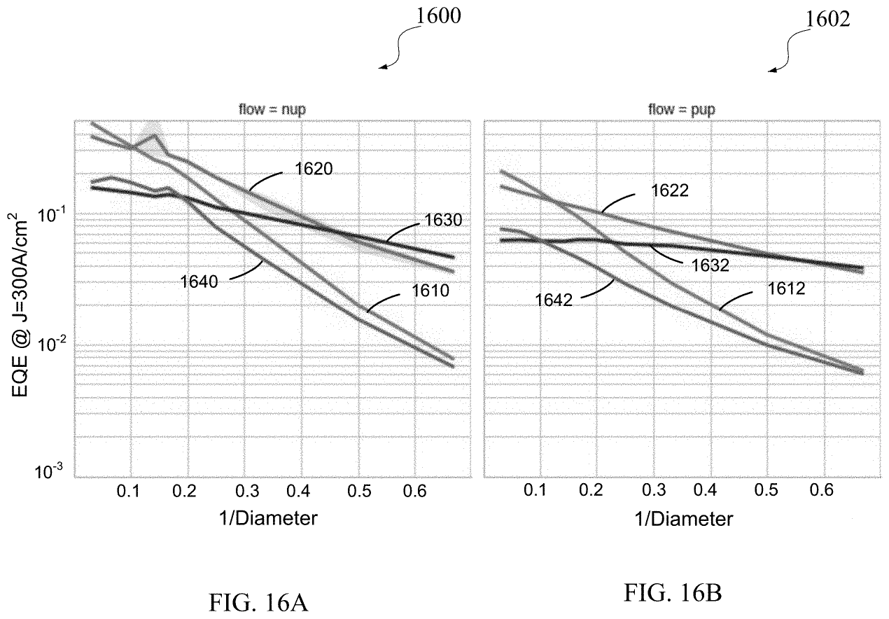

FIG. 16A includes a diagram 1600 illustrating external quantum efficiencies of examples of n-side-up micro-LEDs having different sizes and different doping recipes in the active regions at a same driving current density. In the examples shown in FIG. 16A, the injected current density for the micro-LEDs is about 300 A/cm². A curve 1610 in FIG. 16A shows the external quantum efficiencies of micro-LEDs having different sizes and without doping in the active regions at the same current density. A curve 1620 in FIG. 16A shows the external quantum efficiencies of micro-LEDs having different sizes and with silicon doping in the barrier layers of the active regions, where the doping density is about 1×10¹⁸/cm³. A curve 1630 in FIG. 16A shows the external quantum efficiencies of micro-LEDs having different sizes and with silicon doping in the barrier layers of the active regions, where the doping density is about 4×10¹⁸/cm³. A curve 1640 in FIG. 16A shows the external quantum efficiencies of micro-LEDs having different sizes and with magnesium doping in the barrier layers of the active regions.

FIG. 16A shows that, for small micro-LEDs, such as micro-LEDs with diameters less than about 10 μm, the EQEs of micro-LEDs with a silicon doping density at about 1×10¹⁸/cm³ in the barrier layers may be higher than the EQEs of micro-LEDs having similar sizes but without doping in the active region, when the current density is the same and has a high value. The improvement may increase as the size of the micro-LED decreases. With a higher silicon doping density (e.g., about 4×10¹⁸/cm³) in the barrier layers, the EQEs of the micro-LEDs having small sizes (e.g., smaller than about 3 μm) may be higher than the EQEs of micro-LEDs having similar sizes but without doping in the active region, when the current density is the same and has a high value. The improvement may increase as the size of the micro-LED decreases. For small micro-LEDs, the EQEs of micro-LEDs with Mg doping in the barrier layers may be much lower than the EQEs of micro-LEDs having similar sizes but without doping in the active region, when the current density is about the same. Thus, FIG. 16A shows the effectiveness of the doping in the active region at a very high current density, which may depend on the doping material, the doping density, and the size of the micro-LED (e.g., the lateral size of the active region).

FIG. 16B includes a diagram 1602 illustrating external quantum efficiencies of examples of p-side-up micro-LEDs having different sizes and different doping recipes in the active region at a same driving current density. The p-side-up micro-LEDs may be formed by growing the active layers on the n-type semiconductor layer and then growing the p-type semiconductor layer on the active layers. In the examples shown in FIG. 16B, the injected current density for the micro-LEDs is about 300 A/cm². A curve 1612 in FIG. 16B shows the external quantum efficiencies of micro-LEDs having different sizes and without doping in the active regions at the same current density. A curve 1622 in FIG. 16B shows the external quantum efficiencies of micro-LEDs having different sizes and with silicon doping in the barrier layers of the active regions, where the doping density is about 1×10¹⁸/cm³. A curve 1632 in FIG. 16B shows the external quantum efficiencies of micro-LEDs having different sizes and with silicon doping in the barrier layers of the active regions, where the doping density is about 4×10¹⁸/cm³. A curve 1642 in FIG. 16B shows the external quantum efficiencies of micro-LEDs having different sizes and with magnesium doping in the barrier layers of the active regions.

FIG. 16B shows that, for small micro-LEDs, such as micro-LEDs with diameters less than about 8 μm, the EQEs of micro-LEDs with a silicon doping density at about 1×10¹⁸/cm³ in the barrier layers may be higher than the EQEs of micro-LEDs having similar sizes but without doping in the active region, when the current density is the same and has a high value. The EQE improvement may increase as the size of the micro-LED decreases. With a higher silicon doping density (e.g., about 4×10¹⁸/cm³) in the barrier layers, the EQEs of the micro-LEDs having small sizes (e.g., smaller than about 4.5 μm) may be higher than the EQEs of micro-LEDs having similar sizes but without doping in the active region, when the current density is the same and has a high value. The EQE improvement may increase as the size of the micro-LED decreases.

For small micro-LEDs, the EQEs of micro-LEDs with Mg doping in the barrier layers may be lower than the EQEs of micro-LEDs having similar sizes but without doping in the active region, when the current density is about the same. Thus, FIG. 16B also shows the effectiveness of the doping in the active region at a very high current density, which may also depend on the doping material, the doping density, and the size of the micro-LED (e.g., the lateral size of the active region).

FIGS. 16A and 16B show that the EQEs can be improved for both p-side-up micro-LEDs and n-side-up micro-LEDs with small sizes even at a very high current density, and the improvement may be more significant for p-side-up micro-LEDs. FIGS. 15-16B show that the sizes of the micro-LEDs with silicon doping and with improved EQE performance, and the amount of the EQE improvement, may also depend on the operation conditions (e.g., the current density) of the micro-LEDs.

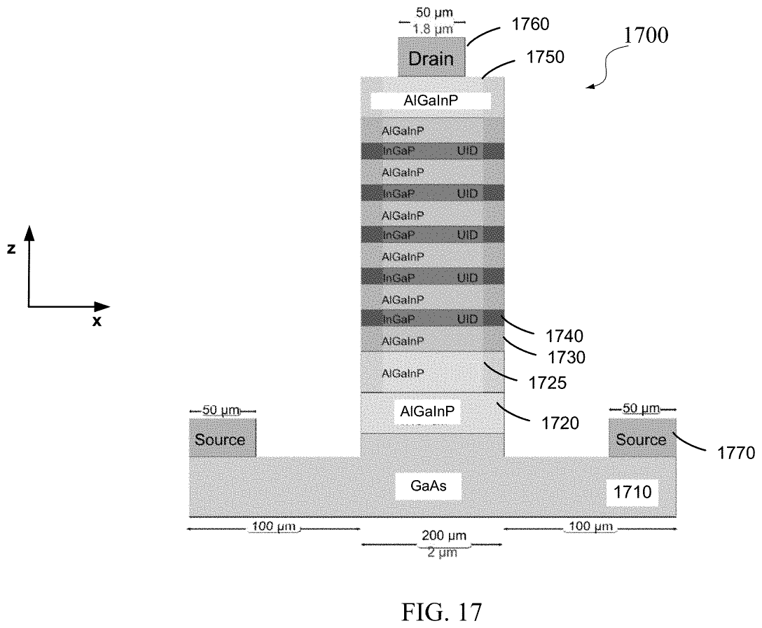

FIG. 17 illustrates an example of a micro-LED structure 1700 used for simulations according to certain embodiments. In the illustrated example, micro-LED structure 1700 may include an n-type substrate 1710 (e.g., n+ GaAs) that may be used as an n-contact layer, another n-contact layer 1720 (e.g., n+ AlGaInP), an n-spreading layer 1725 (e.g., n+ AlGaInP), six barrier layers 1730 (e.g., AlGaInP), five quantum well layers 1740 (e.g., InGaP), a p-spreading layer 1750 (e.g., P++ AlGaInP), a p-contact 1760, and n-contacts 1770. The lateral dimension (the linear dimension of the active region or the mesa structure) of micro-LED structure 1700 used in the simulations may be either about 200 μm or about 2 μm as shown in FIG. 17. The sizes of p-contact 1760 and n-contacts 1770 are also shown in FIG. 17.

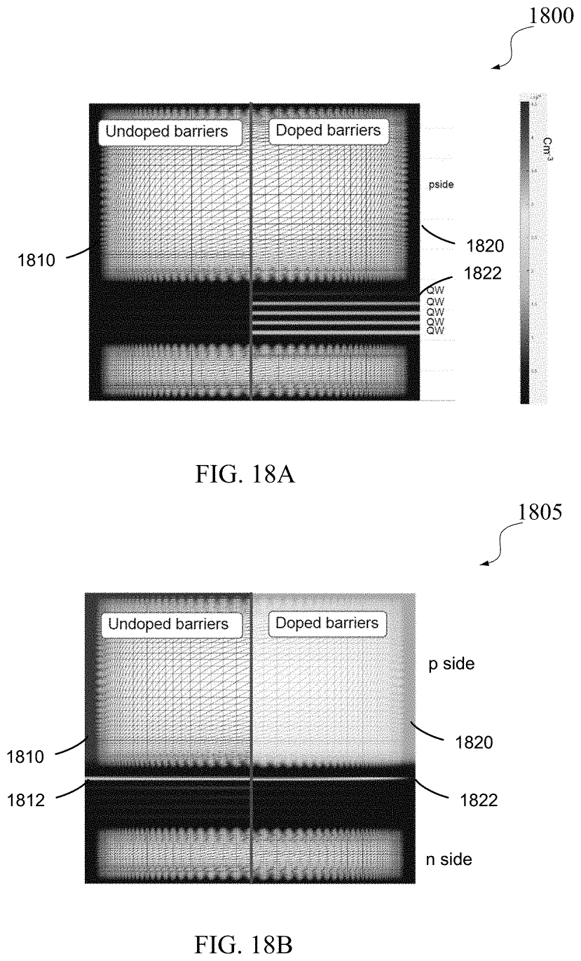

FIG. 18A includes a diagram 1800 illustrating simulated electron densities in the quantum wells of examples of small micro-LEDs without or with doping in the barrier layers according to certain embodiments. The examples of small micro-LEDs used in the simulations may have a structure as shown by micro-LED structure 1700, where the lateral dimension of the mesa structure may be about 2 μm. A micro-LED 1810 shown in the left portion of diagram 1800 may have no doping in the barrier layers (e.g., barrier layer 1730). A micro-LED 1820 shown in the right portion of diagram 1800 may have silicon doping in the barrier layers. The injected current density used for the simulation may be about 10 A/cm². FIG. 18A shows that micro-LED 1820 may have higher electron densities in the quantum well layers (e.g., quantum well layers 1740), where a quantum well layer 1822 that is the closest to the p-side may have a lower electron density than other quantum well layers.

FIG. 18B includes a diagram 1805 illustrating simulated hole densities in the quantum wells of examples of small micro-LEDs without or with doping in the barrier layers according to certain embodiments. The examples of small micro-LEDs used in the simulations may be the same as the small micro-LEDs of FIG. 18A, where the lateral dimension of the mesa structure may be about 2 μm. The injected current density used for the simulation may be about 10 A/cm². FIG. 18B shows that micro-LED 1820 may have a higher hole density in the center region of quantum well layer 1822 that is the closest to the p-side, from which the holes may be injected. In addition, the hole density at the edge of quantum well layer 1822 may be much lower than that in the center region of quantum well layer 1822. In contrast, the hole density at the edge of a quantum well layer 1812 of micro-LED 1810 that is the closest to the p-side may be much higher than that at the edge of quantum well layer 1822. Thus, there may be higher losses due to more non-radiative carrier recombination at the edge of quantum well layer 1812. Therefore, micro-LED 1820 may have a higher EQE than micro-LED 1810.

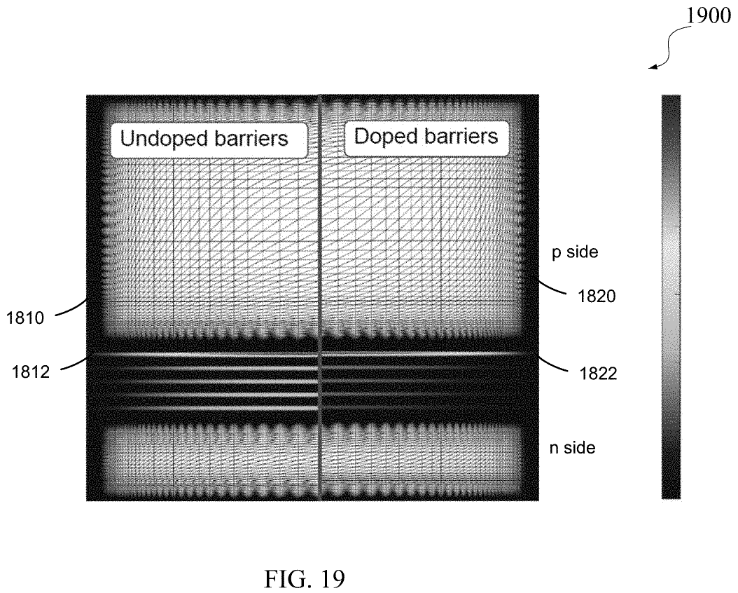

FIG. 19 includes a diagram 1900 illustrating simulated radiative recombination rates in the quantum wells of examples of small micro-LEDs without or with doping in the barrier layers according to certain embodiments. The examples of small micro-LEDs used in the simulation may be the same as the small micro-LEDs 1810 and 1820 of FIGS. 18A and 18B, where the lateral dimension of the mesa structure may be about 2 μm. The injected current density used for the simulation may be about 10 A/cm². FIG. 19 shows that the radiative recombination may mainly occur in the center region of quantum well layer 1822 in micro-LED 1820. In contrast, in micro-LED 1810, significant amounts of the radiative recombination may occur in quantum well layers other than quantum well layer 1812 that is the closest to the p-side.

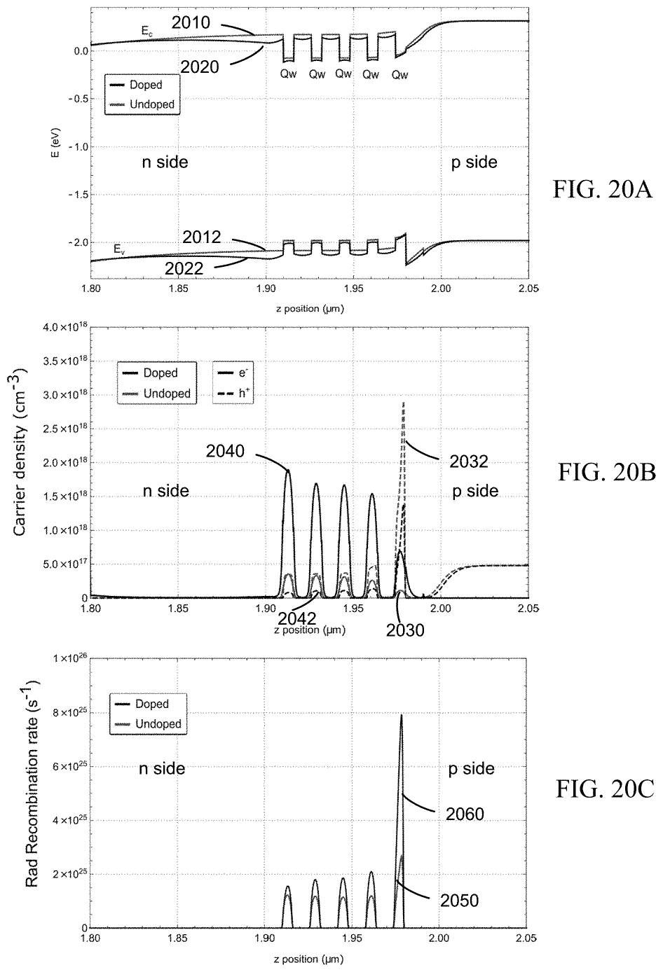

FIG. 20A illustrates the energy bands at the center regions of examples of small micro-LEDs without or with doping in the barrier layers according to certain embodiments. The examples of small micro-LEDs used in the simulations may be the same as micro-LEDs 1810 and 1820 of FIGS. 18A and 18B, where the lateral dimension of the mesa structure may be about 2 μm. The injected current density used for the simulations may be about 10 A/cm². In FIG. 20A, a curve 2010 and a curve 2012 show the conduction band and the valence band, respectively, at the center region of micro-LED 1810. A curve 2020 and a curve 2022 show the conduction band and the valence band, respectively, at the center region of micro-LED 1820.

FIG. 20B illustrates carrier densities in different layers of examples of small micro-LEDs without or with doping in the barrier layers according to certain embodiments. The examples of small micro-LEDs used in the simulation may be the same as micro-LEDs 1810 and 1820 of FIGS. 18A and 18B, where the lateral dimension of the mesa structure may be about 2 μm. The injected current density used for the simulation may be about 10 A/cm². In FIG. 20B, a curve 2030 and a curve 2032 show the electron density and the hole density, respectively, at the center region of micro-LED 1810. A curve 2040 and a curve 2042 show the electron density and the hole density, respectively, at the center region of micro-LED 1820. As FIG. 18A, FIG. 20B also shows that micro-LED 1820 may have higher electron densities in the quantum well layers, where quantum well layer 1822 that is the closest to the p-side may have a lower electron density than other quantum well layers. As FIG. 18B, FIG. 20B also shows that micro-LEDs 1810 and 1820 may both have a higher hole density in the center region of the quantum well layer that is the closest to the p-side. FIG. 20B also shows that the hole density and the electron density may be comparable in quantum well layer 1822 of micro-LED 1820, whereas the hole density and the electron density may be very different in quantum well layer 1812 of micro-LED 1810.

FIG. 20C illustrates radiative recombination rates in different layers of examples of small micro-LEDs without or with doping in the barrier layers according to certain embodiments. The examples of small micro-LEDs used in the simulation may be the same as micro-LEDs 1810 and 1820 of FIGS. 18A and 18B, where the lateral dimension of the mesa structure may be about 2 μm. The injected current density used for the simulation may be about 10 A/cm². In FIG. 20C, a curve 2050 shows the radiative recombination rates in different layers of micro-LED 1810 that has no doping in the barrier layers. A curve 2060 shows the radiative recombination rates in different layers of micro-LED 1820 that has silicon doping in the barrier layers. As in FIG. 19, curves 2050 and 2060 in FIG. 20C show that the radiative recombination may mainly occur in the center region of quantum well layer 1822 in micro-LED 1820, whereas significant amounts of the radiative recombination may occur in quantum well layers other than quantum well layer 1812 in micro-LED 1810. In addition, micro-LED 1820 may have a much higher radiative recombination rate at the center region of the quantum well layer closest to the p-side than micro-LED 1810. As such, in micro-LED 1820, the loss of carriers due to the non-radiative recombination at the edges of quantum well layer 1822 may be lower and thus the quantum efficiency of micro-LED 1820 may be higher.

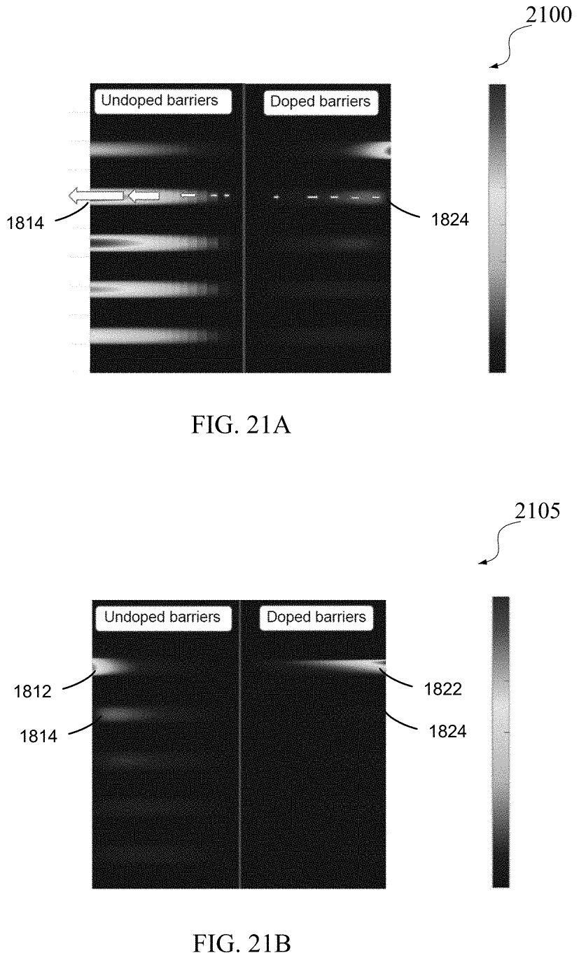

FIG. 21A includes a diagram 2100 illustrating simulated lateral electron current densities in quantum wells of examples of small micro-LEDs without or with doping in the barrier layers according to certain embodiments. The examples of small micro-LEDs used in the simulation may be the same as micro-LEDs 1810 and 1820 of FIGS. 18A and 18B, where the lateral dimension of the mesa structure may be about 2 μm. The injected current density used for the simulation may be about 10 A/cm². FIG. 21A shows that, in micro-LED 1820 with silicon doping in the barrier layers, the lateral electron current in quantum well layers (e.g., quantum well layer 1824) below the quantum well layer (e.g., quantum well layer 1822) that is the closest to the p-side may be much lower than that in quantum well layers 1814 of micro-LED 1810.

FIG. 21B includes a diagram 2105 illustrating simulated lateral hole current densities in quantum wells of examples of small micro-LEDs without or with doping in the barrier layers according to certain embodiments. The examples of small micro-LEDs used in the simulation may be the same as micro-LEDs 1810 and 1820 of FIGS. 18A and 18B, where the lateral dimension of the mesa structure may be about 2 μm. The injected current density used for the simulation may be about 10 A/cm². FIG. 21B shows that, in micro-LED 1820 with silicon doping in the barrier layers, the lateral hole current in quantum well layers (e.g., quantum well layer 1824) below the quantum well layer (e.g., quantum well layer 1822) that is closest to the p-side may be much lower than that in quantum well layers 1814 of micro-LED 1810.

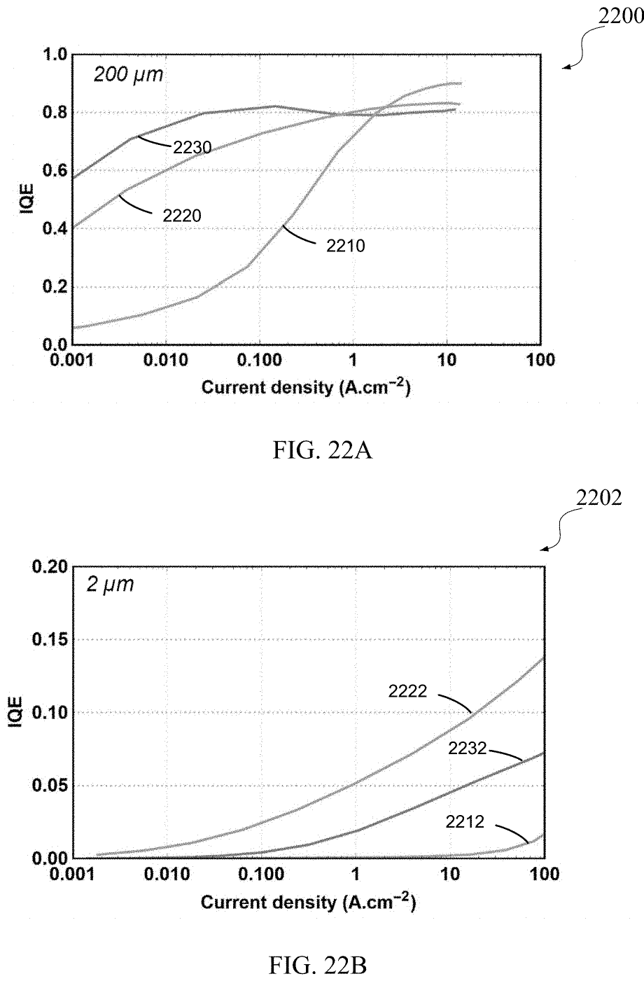

FIG. 22A includes a diagram 2200 illustrating simulated internal quantum efficiencies of examples of large micro-LEDs having different doping recipes in the active regions at different injected current densities. The examples of micro-LEDs used in the simulations may have the same structure as micro-LED structure 1700 and may have mesas with a diameter about 200 μm. In FIG. 22A, a curve 2210 shows the IQE of a micro-LED with no doping in the active region as a function of the current density, a curve 2220 shows the IQE of a micro-LED with silicon doping in the barrier layers of the active region as a function of the current density, and a curve 2230 shows the IQE of a micro-LED with magnesium doping in the barrier layers of the active region as a function of the current density. FIG. 22A shows that, at lower current densities, such as below about 1 A/cm², the IQE may be improved by either silicon or magnesium doping in the barrier layers of the active region, but the IQE may be degraded by the silicon or magnesium doping in the barrier layers at higher current densities, such as above 1 A/cm².

FIG. 22B includes a diagram 2202 illustrating simulated internal quantum efficiencies of examples of small micro-LEDs having different doping recipes in the active regions at different injected current densities. The examples of micro-LEDs used in the simulation may have the same structure as micro-LED structure 1700 and may have mesas with a diameter about 2 μm. In FIG. 22B, a curve 2212 shows the IQE of a micro-LED with no doping in the active region as a function of the current density, a curve 2222 shows the IQE of a micro-LED with silicon doping in the barrier layers of the active region as a function of the current density, and a curve 2232 shows the IQE of a micro-LED with magnesium doping in the barrier layers of the active region as a function of the current density. FIG. 22B shows that the IQEs of small micro-LEDs may be improved by either silicon or magnesium doping in the barrier layers of the active regions at both low and high current densities.

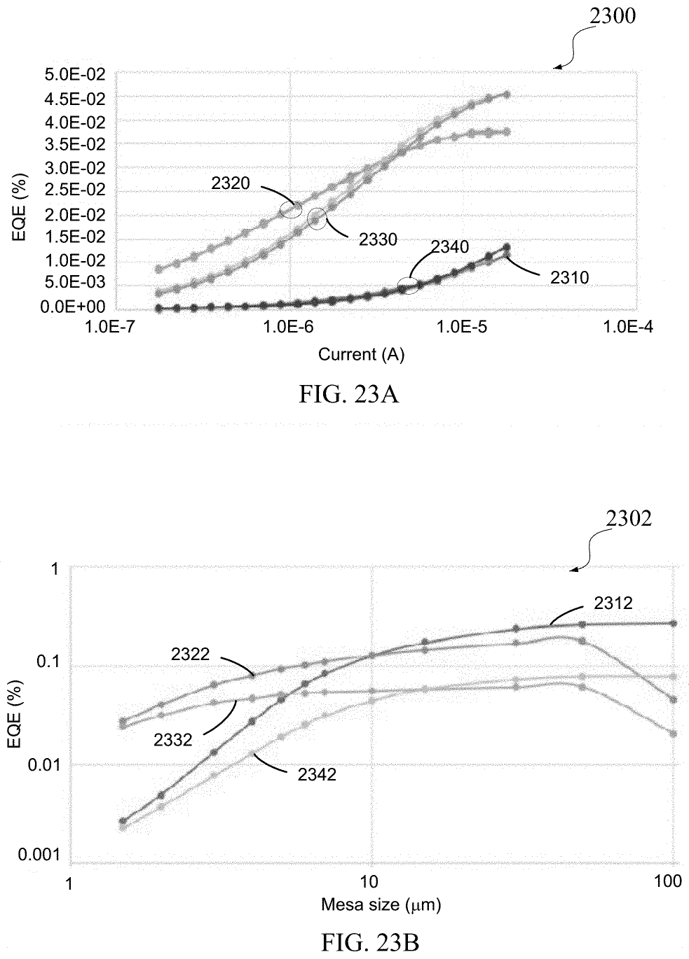

FIG. 23A includes a diagram 2300 illustrating measured external quantum efficiencies of examples of small micro-LEDs having the same size but different doping recipes in the active regions at different injected current densities. In the illustrated examples, the small micro-LEDs may have a diameter of about 1.5 μm. FIG. 23A includes a curve 2310 showing the measured EQEs of micro-LEDs (on a reference wafer) with no doping in the active region as a function of the injected current or current density. Because of the small sizes of the micro-LEDs, the current densities may be very high at the currents shown in FIG. 23A.

Curves 2320 show the measured EQEs of micro-LEDs on two wafers with silicon doped in the barrier layers at a doping density of about 1×10¹⁸ cm³ as a function of the injected current or current density. Curves 2330 show the measured EQEs of micro-LEDs on two wafers with silicon doped in the barrier layers at a doping density of 4×10¹⁸ cm³ as a function of the injected current or current density. Curves 2340 show the measured EQEs of micro-LEDs on two wafers with magnesium doping in the barrier layers as a function of the injected current or current density. FIG. 23A shows that the EQEs of small micro-LEDs at both high and low currents (or current densities) may be improved by the silicon doping in the barrier layers.

FIG. 23B includes a diagram 2302 illustrating measured external quantum efficiencies of examples of micro-LEDs having different sizes and different doping recipes in the active regions at a same injected current density. The injected current density used in the measurement is about 130 A/cm². The horizontal axis of FIG. 23B corresponds to the lateral linear dimension (in a log scale) of the mesa structure of a micro-LED. The vertical axis of FIG. 23B corresponds to the EQE (in a log scale) of the micro-LED. A curve 2312 in FIG. 23B shows the measured EQEs of micro-LEDs having different sizes and with no doping in the active region. A curve 2322 shows the measured EQEs of micro-LEDs having different sizes and with silicon doped at a doping density about 1×10¹⁸ cm³ in the barrier layers. A curve 2332 shows the measured EQEs of micro-LEDs having different sizes and with silicon doped at a doping density about 4×10¹⁸ cm³ in the barrier layers. A curve 2342 shows the measured EQEs of micro-LEDs having different sizes and with magnesium doping in the barrier layers of the active region.

The measurement results shown in FIG. 23B again show that doping silicon in the barrier layers of small micro-LEDs may improve the EQEs of the micro-LEDs even at high current densities. The measurement results shown in FIG. 23B also show that, the maximum size of the small micro-LEDs that can achieve improved EQEs at high current densities by silicon doping in the barrier layers may depend on the doping density. For example, FIG. 23B shows that, at a silicon doping density about 1×10¹⁸ cm³ and a current density about 130 A/cm², the EQEs of micro-LEDs with mesas having lateral sizes less than about 10 μm may be improved by the silicon doping in the barrier layers. At a silicon doping density about 4×10¹⁸ cm³ and a current density about 130 A/cm², the EQEs of micro-LEDs with mesas having lateral sizes less than about 7 μm may be improved by the silicon doping in the barrier layers.

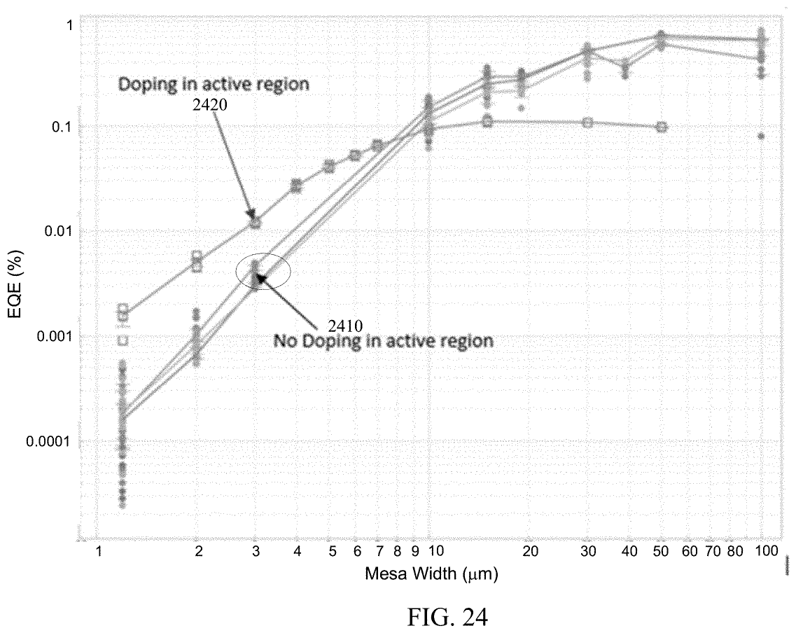

FIG. 24 illustrates additional measurement results showing efficiency improvement for examples of micro-LEDs with dopants in the active regions according to certain embodiments. In FIG. 24, the abscissa corresponds to the device lateral size (e.g., width or diameter of the mesa structure) in logarithmic scale, and the ordinate corresponds to the EQE in logarithmic scale. Curves 2410 show the EQEs of micro-LED devices without dopants in the active region as a function of the device size. A curve 2420 shows the EQEs of micro-LEDs with dopants introduced in the active region as a function of the device size. As shown in FIG. 24, for small micro-LEDs, such as micro-LEDs with mesa width (or diameter) less than about 10 μm, introducing dopants in the barrier layers of the active region can significantly improve the EQEs of the devices.

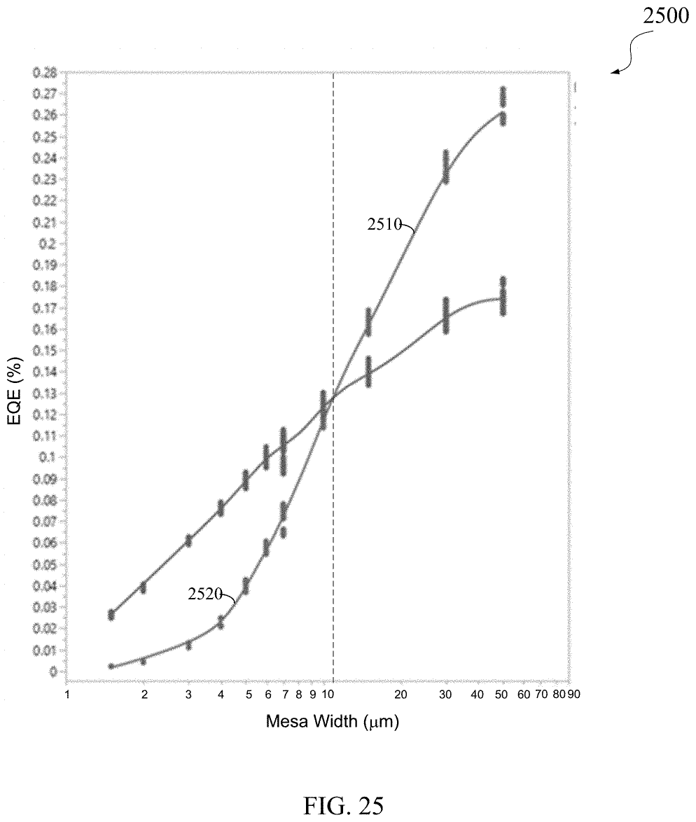

FIG. 25 includes a diagram 2500 illustrating additional measured external quantum efficiencies of examples of micro-LEDs having different lateral sizes and with or without dopants in the active regions, where the current density is about 100 A/cm³. The doping density of silicon dopants in the barrier layers of the micro-LEDs with silicon doping in the active regions is about 1×10¹⁸/cm³. A curve 2510 illustrates the EQEs of examples of micro-LEDs having different lateral sizes and without dopants in the active regions. A curve 2520 illustrates the EQEs of examples of micro-LEDs having different lateral sizes and with dopants in the active regions. As shown by curves 2510 and 2520, for micro-LEDs with lateral sizes greater than about 10 μm, doping in the active region may reduce the EQEs at high current densities. However, for micro-LEDs with lateral sizes less than about 10 μm, doping in the active region can significantly improve the EQEs, even at high current densities.

Thus, even though doping in the active regions is generally not desired in large micro-LEDs due to degraded performance, both the simulation results and the measurement results disclosed herein show that, for red micro-LED devices (e.g., AlGaInP, InGaAlAsP, or AlGaAs micro-LEDs) with lateral sizes less than certain threshold values, doping in the active regions can not only improve the quantum efficiencies at low current densities (e.g., less than about 1 A/cm²), but can also significantly improve the external quantum efficiency at the device operation conditions, for example, with current densities greater than about 10 A/cm², due to the suppression of surface losses. The EQE improvement may also depend on the doping density. For example, the EQE may be improved when the silicon doping densities range from about 1×10¹⁷/cm³ to about 5×10¹⁸/cm³ or to about 1×10¹⁹/cm³. The EQE improvement may also depend on the doping material. For example, doping the barrier layers with n-type doping materials, such as silicon, selenium, or tellurium, which may not diffuse into the adjacent quantum well during the epitaxial growth, may improve the EQEs more than doping the barrier layers with p-type doping materials, such as Mg. The dopants may only need to be added in one or more but not all barrier layers and/or may only need to be added in a portion (e.g., a middle portion) of a barrier layer.

The simulation results and the measurement results also show that the maximum size of small micro-LEDs with doping in the active region and having improved internal and external quantum efficiencies may be, for example, less than about 20 μm, less than about 10 μm, or less than about 8 μm, which may be different for different doping densities and/or different operating current densities. In addition, in certain conditions, p-side-up micro-LEDs may experience more EQE improvement by the doping in the barrier layers of the active regions than n-side-up micro-LEDs.

The simulation results further show that, for a small micro-LED with doping in the active region that includes a MQW structure, the radiative recombination may mainly occur in one quantum well, such as the quantum well that is the closest to the p-type semiconductor region that injects holes into the active region. Therefore, small micro-LEDs having a single quantum well and silicon doping in one or two barrier layers may achieve the same EQEs and power as micro-LEDs having similar lateral sizes but with multiple quantum wells.

One or two-dimensional arrays of the LEDs described above may be manufactured on a wafer to form light sources (e.g., light source 642). Driver circuits (e.g., driver circuit 644) may be fabricated, for example, on a silicon wafer using CMOS processes. The LEDs and the driver circuits on wafers may be diced and then bonded together, or may be bonded on the wafer level and then diced. Various bonding techniques can be used for bonding the LEDs and the driver circuits, such as adhesive bonding, metal-to-metal bonding, metal oxide bonding, wafer-to-wafer bonding, die-to-wafer bonding, hybrid bonding, and the like.

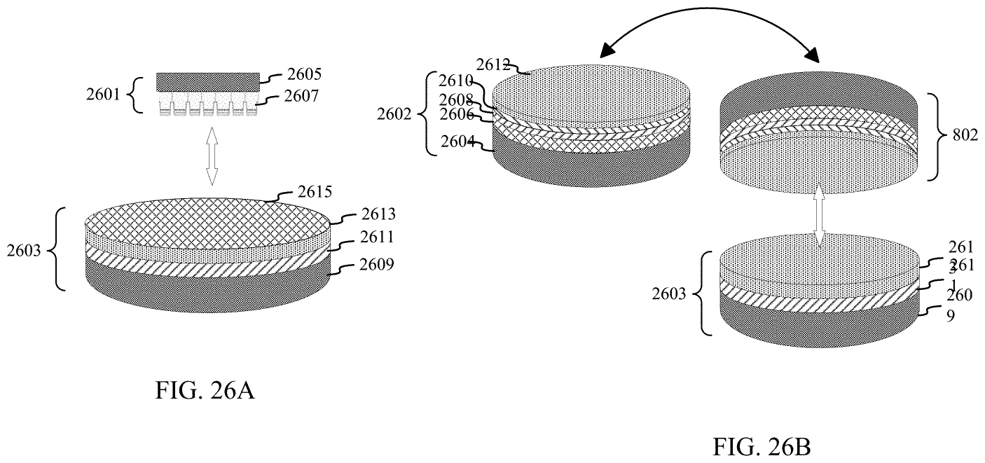

FIG. 26A illustrates an example of a method of die-to-wafer bonding for arrays of LEDs according to certain embodiments. In the example shown in FIG. 26A, an LED array 2601 may include a plurality of LEDs 2607 on a carrier substrate 2605. Carrier substrate 2605 may include various materials, such as GaAs, InP, GaN, AlN, sapphire, SiC, Si, or the like. LEDs 2607 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (AlGaIn)Pas, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 2603 may include a base layer 2609 having passive or active integrated circuits (e.g., driver circuits 2611) fabricated thereon. Base layer 2609 may include, for example, a silicon wafer. Driver circuits 2611 may be used to control the operations of LEDs 2607. For example, the driver circuit for each LED 2607 may include a 2T1C pixel structure that has two transistors and one capacitor. Wafer 2603 may also include a bonding layer 2613. Bonding layer 2613 may include various materials, such as a metal, an oxide, a dielectric, CuSn, AuTi, and the like. In some embodiments, a patterned layer 2615 may be formed on a surface of bonding layer 2613, where patterned layer 2615 may include a metallic grid made of a conductive material, such as Cu, Ag, Au, Al, or the like.

LED array 2601 may be bonded to wafer 2603 via bonding layer 2613 or patterned layer 2615. For example, patterned layer 2615 may include metal pads or bumps made of various materials, such as CuSn, AuSn, or nanoporous Au, that may be used to align LEDs 2607 of LED array 2601 with corresponding driver circuits 2611 on wafer 2603. In one example, LED array 2601 may be brought toward wafer 2603 until LEDs 2607 come into contact with respective metal pads or bumps corresponding to driver circuits 2611. Some or all of LEDs 2607 may be aligned with driver circuits 2611, and may then be bonded to wafer 2603 via patterned layer 2615 by various bonding techniques, such as metal-to-metal bonding. After LEDs 2607 have been bonded to wafer 2603, carrier substrate 2605 may be removed from LEDs 2607.

FIG. 26B illustrates an example of a method of wafer-to-wafer bonding for arrays of LEDs according to certain embodiments. As shown in FIG. 26B, a first wafer 2602 may include a substrate 2604, a first semiconductor layer 2606, active layers 2608, and a second semiconductor layer 2610. Substrate 2604 may include various materials, such as GaAs, InP, GaN, AlN, sapphire, SiC, Si, or the like. First semiconductor layer 2606, active layers 2608, and second semiconductor layer 2610 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 2606 may be an n-type layer, and second semiconductor layer 2610 may be a p-type layer. For example, first semiconductor layer 2606 may be an n-doped GaN layer (e.g., doped with Si or Ge), and second semiconductor layer 2610 may be a p-doped GaN layer (e.g., doped with Mg, Ca, Zn, or Be). Active layers 2608 may include, for example, one or more GaN layers, one or more InGaN layers, one or more AlGaInP layers, and the like, which may form one or more heterostructures, such as one or more quantum wells or MQWs.

In some embodiments, first wafer 2602 may also include a bonding layer. Bonding layer 2612 may include various materials, such as a metal, an oxide, a dielectric, CuSn, AuTi, or the like. In one example, bonding layer 2612 may include p-contacts and/or n-contacts (not shown). In some embodiments, other layers may also be included on first wafer 2602, such as a buffer layer between substrate 2604 and first semiconductor layer 2606. The buffer layer may include various materials, such as polycrystalline GaN or AlN. In some embodiments, a contact layer may be between second semiconductor layer 2610 and bonding layer 2612. The contact layer may include any suitable material for providing an electrical contact to second semiconductor layer 2610 and/or first semiconductor layer 2606.

First wafer 2602 may be bonded to wafer 2603 that includes driver circuits 2611 and bonding layer 2613 as described above, via bonding layer 2613 and/or bonding layer 2612. Bonding layer 2612 and bonding layer 2613 may be made of the same material or different materials. Bonding layer 2613 and bonding layer 2612 may be substantially flat. First wafer 2602 may be bonded to wafer 2603 by various methods, such as metal-to-metal bonding, eutectic bonding, metal oxide bonding, anodic bonding, thermo-compression bonding, ultraviolet (UV) bonding, and/or fusion bonding.

As shown in FIG. 26B, first wafer 2602 may be bonded to wafer 2603 with the p-side (e.g., second semiconductor layer 2610) of first wafer 2602 facing down (i.e., toward wafer 2603). After bonding, substrate 2604 may be removed from first wafer 2602, and first wafer 2602 may then be processed from the n-side. The processing may include, for example, the formation of certain mesa shapes for individual LEDs, as well as the formation of optical components corresponding to the individual LEDs.

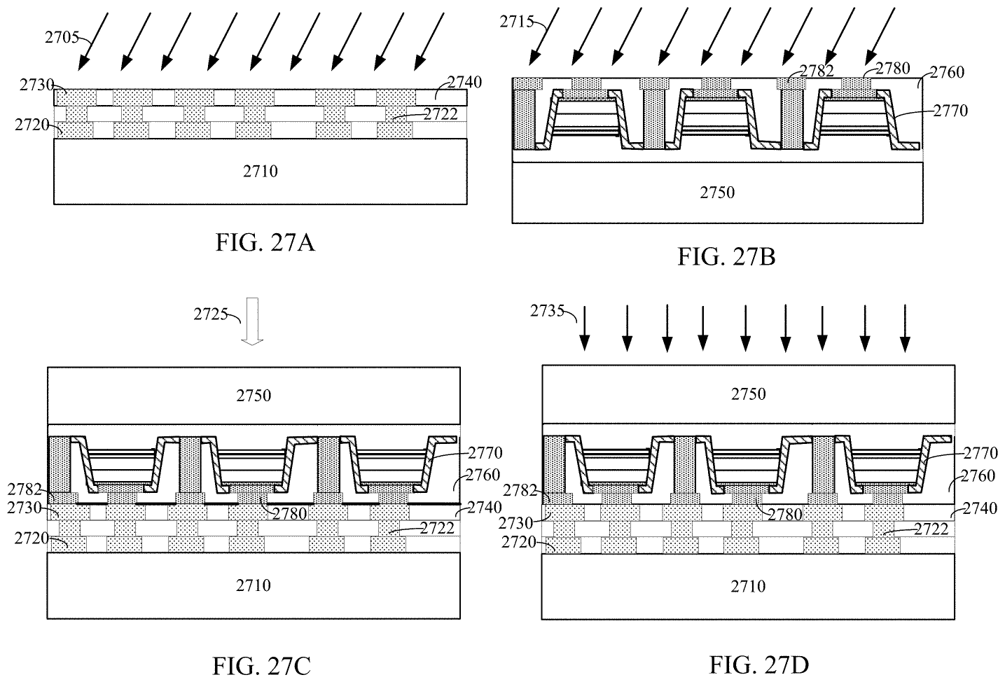

FIGS. 27A-27D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 27A shows a substrate 2710 with passive or active circuits 2720 manufactured thereon. As described above with respect to FIGS. 26A-26B, substrate 2710 may include, for example, a silicon wafer. Circuits 2720 may include driver circuits for the arrays of LEDs. A bonding layer may include dielectric regions 2740 and contact pads 2730 connected to circuits 2720 through electrical interconnects 2722. Contact pads 2730 may include, for example, Cu, Ag, Au, Al, W, Mo, Ni, Ti, Pt, Pd, or the like. Dielectric materials in dielectric regions 2740 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 2705. The activated surface may be atomically clean and may be reactive for formation of direct bonds between wafers when they are brought into contact, for example, at room temperature.

FIG. 27B illustrates a wafer 2750 including an array of micro-LEDs 2770 fabricated thereon as described above with respect to, for example, FIGS. 7A, 7B, 26A, and 26B. Wafer 2750 may be a carrier wafer and may include, for example, GaAs, InP, GaN, AlN, sapphire, SiC, Si, or the like. Micro-LEDs 2770 may include an n-type layer, an active region, and a p-type layer epitaxially grown on wafer 2750. The epitaxial layers may include various III-V semiconductor materials described above, and may be processed from the p-type layer side to etch mesa structures in the epitaxial layers, such as substantially vertical structures, parabolic structures, conical structures, or the like. Passivation layers and/or reflection layers may be formed on the sidewalls of the mesa structures. P-contacts 2780 and n-contacts 2782 may be formed in a dielectric material layer 2760 deposited on the mesa structures and may make electrical contacts with the p-type layer and the n-type layers, respectively. Dielectric materials in dielectric material layer 2760 may include, for example, SiCN, SiO₂, SiN, Al₂O₃, HfO₂, ZrO₂, Ta₂O₅, or the like. P-contacts 2780 and n-contacts 2782 may include, for example, Cu, Ag, Au, Al, W, Mo, Ni, Ti, Pt, Pd, or the like. The top surfaces of p-contacts 2780, n-contacts 2782, and dielectric material layer 2760 may form a bonding layer. The bonding layer may be planarized and polished using, for example, chemical mechanical polishing, where the polishing may cause dishing in p-contacts 2780 and n-contacts 2782. The bonding layer may then be cleaned and activated by, for example, an ion (e.g., plasma) or fast atom (e.g., Ar) beam 2715. The activated surface may be atomically clean and reactive for formation of direct bonds between wafers when they are brought into contact, for example, at room temperature.

FIG. 27C illustrates a room temperature bonding process for bonding the dielectric materials in the bonding layers. For example, after the bonding layer that includes dielectric regions 2740 and contact pads 2730 and the bonding layer that includes p-contacts 2780, n-contacts 2782, and dielectric material layer 2760 are surface activated, wafer 2750 and micro-LEDs 2770 may be turned upside down and brought into contact with substrate 2710 and the circuits formed thereon. In some embodiments, compression pressure 2725 may be applied to substrate 2710 and wafer 2750 such that the bonding layers are pressed against each other. Due to the surface activation and the dishing in the contacts, dielectric regions 2740 and dielectric material layer 2760 may be in direct contact because of the surface attractive force, and may react and form chemical bonds between them because the surface atoms may have dangling bonds and may be in unstable energy states after the activation. Thus, the dielectric materials in dielectric regions 2740 and dielectric material layer 2760 may be bonded together with or without heat treatment or pressure.

FIG. 27D illustrates an annealing process for bonding the contacts in the bonding layers after bonding the dielectric materials in the bonding layers. For example, contact pads 2730 and p-contacts 2780 or n-contacts 2782 may be bonded together by annealing at, for example, about 200-400° C. or higher. During the annealing process, heat 2735 may cause the contacts to expand more than the dielectric materials (due to different coefficients of thermal expansion), and thus may close the dishing gaps between the contacts such that contact pads 2730 and p-contacts 2780 or n-contacts 2782 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the driver circuits, the substrate on which the micro-LEDs are fabricated may be thinned or removed, and various secondary optical components may be fabricated on the light-emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

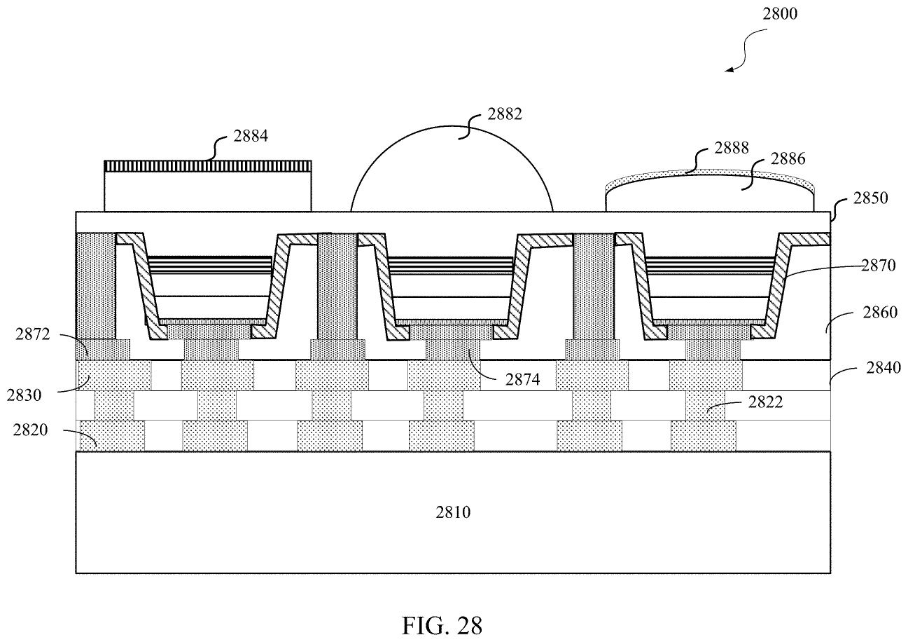

FIG. 28 illustrates an example of an LED array 2800 with secondary optical components fabricated thereon according to certain embodiments. LED array 2800 may be made by bonding an LED chip or wafer with a silicon wafer including electrical circuits fabricated thereon, using any suitable bonding techniques described above with respect to, for example, FIGS. 26A-27D. In the example shown in FIG. 28, LED array 2800 may be bonded using a wafer-to-wafer hybrid bonding technique as described above with respect to FIG. 27A-27D. LED array 2800 may include a substrate 2810, which may be, for example, a silicon wafer. Integrated circuits 2820, such as LED driver circuits, may be fabricated on substrate 2810. Integrated circuits 2820 may be connected to p-contacts 2874 and n-contacts 2872 of micro-LEDs 2870 through interconnects 2822 and contact pads 2830, where contact pads 2830 may form metallic bonds with p-contacts 2874 and n-contacts 2872. Dielectric layer 2840 on substrate 2810 may be bonded to dielectric layer 2860 through fusion bonding.

The substrate (not shown) of the LED chip or wafer may be thinned or may be removed to expose the n-type layer 2850 of micro-LEDs 2870. Various secondary optical components, such as a spherical micro-lens 2882, a grating 2884, a micro-lens 2886, an antireflection layer 2888, and the like, may be formed in or on top of n-type layer 2850. For example, spherical micro-lens arrays may be etched in the semiconductor materials of micro-LEDs 2870 using a gray-scale mask and a photoresist with a linear response to exposure light, or using an etch mask formed by thermal reflowing of a patterned photoresist layer. The secondary optical components may also be etched in a dielectric layer deposited on n-type layer 2850 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 2870 may have multiple corresponding secondary optical components, such as a micro-lens and an anti-reflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 28 to show some examples of secondary optical components that can be formed on micro-LEDs 2870, which does not necessary imply that different secondary optical components are used simultaneously for every LED array.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

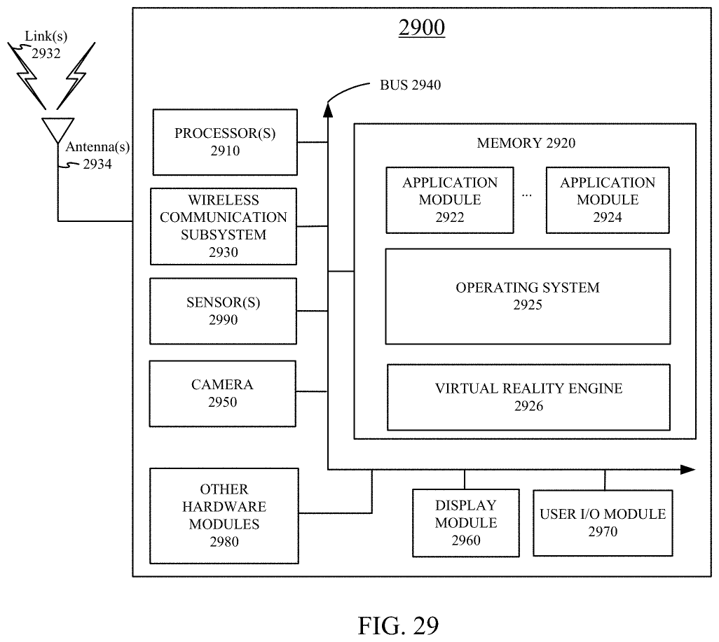

FIG. 29 is a simplified block diagram of an example electronic system 2900 of an example near-eye display (e.g., HMD device) for implementing some of the examples disclosed herein. Electronic system 2900 may be used as the electronic system of an HMD device or other near-eye displays described above. In this example, electronic system 2900 may include one or more processor(s) 2910 and a memory 2920. Processor(s) 2910 may be configured to execute instructions for performing operations at a number of components, and can be, for example, a general-purpose processor or microprocessor suitable for implementation within a portable electronic device. Processor(s) 2910 may be communicatively coupled with a plurality of components within electronic system 2900. To realize this communicative coupling, processor(s) 2910 may communicate with the other illustrated components across a bus 2940. Bus 2940 may be any subsystem adapted to transfer data within electronic system 2900. Bus 2940 may include a plurality of computer buses and additional circuitry to transfer data.

Memory 2920 may be coupled to processor(s) 2910. In some embodiments, memory 2920 may offer both short-term and long-term storage and may be divided into several units. Memory 2920 may be volatile, such as static random access memory (SRAM) and/or dynamic random access memory (DRAM) and/or non-volatile, such as read-only memory (ROM), flash memory, and the like. Furthermore, memory 2920 may include removable storage devices, such as secure digital (SD) cards. Memory 2920 may provide storage of computer-readable instructions, data structures, program modules, and other data for electronic system 2900. In some embodiments, memory 2920 may be distributed into different hardware modules. A set of instructions and/or code might be stored on memory 2920. The instructions might take the form of executable code that may be executable by electronic system 2900, and/or might take the form of source and/or installable code, which, upon compilation and/or installation on electronic system 2900 (e.g., using any of a variety of generally available compilers, installation programs, compression/decompression utilities, etc.), may take the form of executable code.

In some embodiments, memory 2920 may store a plurality of application modules 2922 through 2924, which may include any number of applications. Examples of applications may include gaming applications, conferencing applications, video playback applications, or other suitable applications. The applications may include a depth sensing function or eye tracking function. Application modules 2922-2924 may include particular instructions to be executed by processor(s) 2910. In some embodiments, certain applications or parts of application modules 2922-2924 may be executable by other hardware modules 2980. In certain embodiments, memory 2920 may additionally include secure memory, which may include additional security controls to prevent copying or other unauthorized access to secure information.

In some embodiments, memory 2920 may include an operating system 2925 loaded therein. Operating system 2925 may be operable to initiate the execution of the instructions provided by application modules 2922-2924 and/or manage other hardware modules 2980 as well as interfaces with a wireless communication subsystem 2930 which may include one or more wireless transceivers. Operating system 2925 may be adapted to perform other operations across the components of electronic system 2900 including threading, resource management, data storage control and other similar functionality.

Wireless communication subsystem 2930 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 2900 may include one or more antennas 2934 for wireless communication as part of wireless communication subsystem 2930 or as a separate component coupled to any portion of the system. Depending on desired functionality, wireless communication subsystem 2930 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 2930 may permit data to be exchanged with a network, other computer systems, and/or any other devices described herein. Wireless communication subsystem 2930 may include a means for transmitting or receiving data, such as identifiers of HMD devices, position data, a geographic map, a heat map, photos, or videos, using antenna(s) 2934 and wireless link(s) 2932. Wireless communication subsystem 2930, processor(s) 2910, and memory 2920 may together comprise at least a part of one or more of a means for performing some functions disclosed herein.

Embodiments of electronic system 2900 may also include one or more sensors 2990. Sensor(s) 2990 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 2990 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 2900 may include a display module 2960. Display module 2960 may be a near-eye display, and may graphically present information, such as images, videos, and various instructions, from electronic system 2900 to a user. Such information may be derived from one or more application modules 2922-2924, virtual reality engine 2926, one or more other hardware modules 2980, a combination thereof, or any other suitable means for resolving graphical content for the user (e.g., by operating system 2925). Display module 2960 may use LCD technology, LED technology (including, for example, OLED, ILED, μ-LED, AMOLED, TOLED, etc.), light-emitting polymer display (LPD) technology, or some other display technology.

Electronic system 2900 may include a user input/output module 2970. User input/output module 2970 may allow a user to send action requests to electronic system 2900. An action request may be a request to perform a particular action. For example, an action request may be to start or end an application or to perform a particular action within the application. User input/output module 2970 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 2900. In some embodiments, user input/output module 2970 may provide haptic feedback to the user in accordance with instructions received from electronic system 2900. For example, the haptic feedback may be provided when an action request is received or has been performed.

Electronic system 2900 may include a camera 2950 that may be used to take photos or videos of a user, for example, for tracking the user's eye position. Camera 2950 may also be used to take photos or videos of the environment, for example, for VR, AR, or MR applications. Camera 2950 may include, for example, a complementary metal-oxide-semiconductor (CMOS) image sensor with a few millions or tens of millions of pixels. In some implementations, camera 2950 may include two or more cameras that may be used to capture 3-D images.

In some embodiments, electronic system 2900 may include a plurality of other hardware modules 2980. Each of other hardware modules 2980 may be a physical module within electronic system 2900. While each of other hardware modules 2980 may be permanently configured as a structure, some of other hardware modules 2980 may be temporarily configured to perform specific functions or temporarily activated. Examples of other hardware modules 2980 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 2980 may be implemented in software.

In some embodiments, memory 2920 of electronic system 2900 may also store a virtual reality engine 2926. Virtual reality engine 2926 may execute applications within electronic system 2900 and receive position information, acceleration information, velocity information, predicted future positions, or any combination thereof of the HMD device from the various sensors. In some embodiments, the information received by virtual reality engine 2926 may be used for producing a signal (e.g., display instructions) to display module 2960. For example, if the received information indicates that the user has looked to the left, virtual reality engine 2926 may generate content for the HMD device that mirrors the user's movement in a virtual environment. Additionally, virtual reality engine 2926 may perform an action within an application in response to an action request received from user input/output module 2970 and provide feedback to the user. The provided feedback may be visual, audible, or haptic feedback. In some implementations, processor(s) 2910 may include one or more GPUs that may execute virtual reality engine 2926.

In various implementations, the above-described hardware and modules may be implemented on a single device or on multiple devices that can communicate with one another using wired or wireless connections. For example, in some implementations, some components or modules, such as GPUs, virtual reality engine 2926, and applications (e.g., tracking application), may be implemented on a console separate from the head-mounted display device. In some implementations, one console may be connected to or support more than one HMD.

In alternative configurations, different and/or additional components may be included in electronic system 2900. Similarly, functionality of one or more of the components can be distributed among the components in a manner different from the manner described above. For example, in some embodiments, electronic system 2900 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A light source comprising:
a p-type semiconductor layer;
an n-type semiconductor layer; and
an active region between the p-type semiconductor layer and the n-type semiconductor layer and configured to emit light, the active region including a plurality of barrier layers and one or more quantum well layers, wherein:
the plurality of barrier layers of the active region includes at least one n-doped barrier layer that includes an n-type dopant; and
the active region is characterized by a lateral linear dimension equal to or less than 10 μm.

2. The light source of claim 1, wherein the active region includes an AlInGaP, AlGaAs, or InGaAlAsP based material.

3. The light source of claim 1, wherein the n-type dopant includes silicon, selenium, or tellurium.

4. The light source of claim 1, wherein a concentration of the n-type dopant in the at least one n-doped barrier layer is between 1×10¹⁷/cm³ and 5×10¹⁸/cm³.

5. The light source of claim 1, wherein the lateral linear dimension of the active region is equal to or less than 5 μm.

6. The light source of claim 1, wherein the active region is configured to emit light characterized by a wavelength equal to or greater than 590 nm.

7. The light source of claim 1, wherein the at least one n-doped barrier layer includes an n-doped barrier layer that physically contacts the p-type semiconductor layer.

8. The light source of claim 1, wherein the at least one n-dope barrier layer includes an undoped region between a doped region of the at least one n-doped barrier layer and a quantum well layer of the plurality of quantum well layers.

9. The light source of claim 1, wherein the at least one n-doped barrier layer includes a single n-doped barrier layer that physically contacts the p-type semiconductor layer.

10. The light source of claim 1, wherein the at least one n-doped barrier layer includes two or more n-doped barrier layers.

11. The light source of claim 1, wherein each of the plurality of barrier layers includes the n-type dopant.

12. The light source of claim 1, wherein the n-type dopant is introduced into the at least one n-doped barrier layer during epitaxial growth of the active region.

13. The light source of claim 1, wherein the p-type semiconductor layer is epitaxially grown on the active region.

14. The light source of claim 1, wherein the one or more quantum well layers of the active region include a single quantum well layer.

15. The light source of claim 1, wherein a current density of the light source to achieve a peak efficiency is greater than 10 A/cm².

16. A display device comprising a two-dimensional array of micro-LEDs, each micro-LED of the two-dimensional array of micro-LEDs comprising:
a p-type semiconductor layer;
an n-type semiconductor layer; and
an active region between the p-type semiconductor layer and the n-type semiconductor layer and configured to emit visible light, the active region including a plurality of barrier layers and one or more quantum well layers, wherein:
the plurality of barrier layers of the active region includes at least one n-doped barrier layer that includes an n-type dopant; and
the active region is characterized by a lateral linear dimension equal to or less than 10 μm.

17. The display device of claim 16, wherein the active region includes an AlInGaP, AlGaAs, or InGaAlAsP based material.

18. The display device of claim 16, wherein the n-type dopant includes silicon, selenium, or tellurium.

19. The display device of claim 16, wherein a concentration of the n-type dopant in the at least one n-doped barrier layer is between 1×10¹⁷/cm³ and 5×10¹⁸/cm³.

20. The display device of claim 16, wherein the one or more quantum well layers of the active region include a single quantum well layer.
